(19) United States
(12) Patent Application Publication
(10) Pub. No.: US 2025/0388504 A1
(43) Pub. Date: Dec. 25, 2025

(54) WINDOW MANUFACTURING APPARATUS, METHOD FOR MANUFACTURING WINDOW, AND METHOD FOR MANUFACTURING DISPLAY DEVICE

(71) Applicant: Samsung Display Co., LTD., Yongin-si (KR)

(72) Inventors: TAEWOO PARK, Yongin-si (KR); JEONGWEON SEO, Yongin-si (KR); GWANGTAEK LEE, Yongin-si (KR)

(21) Appl. No.: 19/173,361

(22) Filed: Apr. 8, 2025

(30) Foreign Application Priority Data
Jun. 19, 2024 (KR) 10-2024-0079694

(51) Int. Cl. C03B 23/03; B32B 7/12; B32B 17/10; H04M 1/02; H05K 5/03

(52) U.S. Cl. CPC C03B 23/03; B32B 7/12; B32B 17/10; B32B 2457/20; H04M 1/0268; H05K 5/03

(57) ABSTRACT

A method for manufacturing a display device includes providing a base substrate including a folding part, a first non-folding part, and a second non-folding part, and in which a recessed part is defined in correspondence to the folding part. The method includes forming a resin layer disposed in at least the recessed part, and the forming includes providing a stage including a first part including a curved surface, a second part extending from a side of the first part and including a first flat surface, and a third part extending from an opposite side of the first part and including a second flat surface defining a first angle with the first flat surface. The forming of the resin layer includes forming a preliminary resin layer on the stage, seating the base substrate on the stage, curing the preliminary resin layer, and separating the stage from the base substrate.

This application claims priority to Korean Patent Application No. 10-2024-0079694, filed on Jun. 19, 2024, and all the benefits accruing therefrom under 35 U.S.C. § 119, the content of which in its entirety is herein incorporated by reference.

### BACKGROUND

Embodiments of the present disclosure described herein relate to a window manufacturing apparatus capable of manufacturing a window having an improved folding reliability, a method for manufacturing a window, and a method for manufacturing a display device.

A display device provides information to a user by displaying various images on a display screen. In general, a display device displays information on an allocated screen. Flexible display devices including a flexible display panel that may be folded are being developed. Unlike a rigid display device, a flexible display device may be folded, rolled, or curved. A flexible display device, a shape of which may be changed in various ways, may be carried regardless of the existing screen size, and thus, convenience of the user may be improved.

### SUMMARY

Embodiments of the present disclosure provide a window manufacturing apparatus, and a method for manufacturing a window, by which a window having improved folding reliability and durability may be manufactured.

Embodiments of the present disclosure also provide a method for manufacturing a display device including a window having improved reliability and durability.

According to an embodiment, a method for manufacturing a window includes providing a base substrate including a folding part, a first non-folding part, and a second non-folding part, wherein the first non-folding part and the second non-folding part face each other, with the folding part interposed between the first non-folding part and the second non-folding part, and a recessed part is defined in the base substrate in correspondence to the folding part, and forming a resin layer disposed in at least the recessed part, and the forming of the resin layer includes providing a stage including a first part including a curved surface, a second part extending from a side of the first part and including a first flat surface, and a third part extending from an opposite side of the first part and including a second flat surface defining a first angle with the first flat surface, forming a preliminary resin layer by applying a resin on the stage such that the resin overlaps at least the first part, seating the base substrate on the stage such that the recessed part faces the preliminary resin layer, forming the resin layer by curing the preliminary resin layer, and separating the stage from the base substrate on which the resin layer is formed.

A state, in which the first non-folding part, the folding part, and the second non-folding part are flat, is defined as a first state, a state, in which the folding part is folded such that the base substrate corresponds to a shape of the stage, is defined as a second state, and in the seating of the base substrate on the stage, the base substrate may be changed from the first state to the second state.

In the separating of the stage from the base substrate, the base substrate may be changed from the second state to the first state.

In the second state, an extension plane of the first non-folding part and an extension plane of the second non-folding part may define a second angle, and the second angle may be substantially equal to the first angle.

The base substrate may be a glass substrate.

The first angle may range from 60 degrees to 179.5 degrees.

In the seating of the base substrate on the stage, a filling space may be formed between the recessed part and the first part, and the preliminary resin layer may be disposed in the filling space.

The base substrate may include a first base surface, in which the recessed part is defined, and being adjacent to the stage, and a second base surface facing the first base surface and spaced apart from the stage, and in the seating of the base substrate on the stage, the recessed part may contact the preliminary resin layer, a first portion of the first base surface corresponding to the first non-folding part may contact the second part, and a second portion of the first base surface corresponding to the second non-folding part may contact the third part.

The method may further include pressing the folding part in a direction facing the stage after the seating of the base substrate on the stage, and in the pressing of the folding part, the preliminary resin layer may entirely fill in the recessed part.

The forming of the resin layer may include fixing a shape of the preliminary resin layer filled in the recessed part, through the curing of the preliminary resin layer, and in the separating the stage, the fixed resin layer may be separated from the stage together with the base substrate

The stage may include a hydrophobic material.

The method may further include surface treating each of the curved surface, the first flat surface, and the second flat surface with a hydrophobic material.

According to an embodiment, a method for manufacturing a display device includes providing a display module including a folding display part, a first non-folding display part, and a second non-folding display part, wherein the folding display part is foldable with respect to a folding axis extending in a first direction, and the first non-folding display part and the second non-folding display part are disposed spaced apart from each other in a second direction being perpendicular to the first direction, with the folding display part being interposed between the first non-folding display part and the second non-folding display part, and providing a window on the display module. The providing of the window includes providing a base substrate including a folding part corresponding to the folding display part, a first non-folding part corresponding to the first non-folding display part, and a second non-folding part corresponding to the second non-folding display part, wherein a recessed part is defined in the base substrate in correspondence to the folding part, and forming a resin layer disposed in at least the recessed part, and the forming of the resin layer includes providing a stage including a first part including a curved surface, a second part extending from a side of the first part and including a first flat surface, and a third part extending from an opposite side of the first part and including a second flat surface defining a first angle with the first flat surface, forming a preliminary resin layer by applying a resin on the stage such that the resin overlaps at least the first part, seating the base substrate on the stage such that the recessed part faces the preliminary resin layer, forming the resin layer by curing the preliminary resin layer, and separating the stage from the base substrate on which the resin layer is formed.

The base substrate may include a first base surface, in which the recessed part is defined, and a second base surface facing the first base surface, and the first base surface may be disposed adjacent to the display module.

The base substrate may include a first base surface, in which the recessed part is defined, and a second base surface facing the first base surface, and the second base surface may be disposed adjacent to the display module.

According to an embodiment, a window manufacturing apparatus includes a stage including a first part including a curved surface, a second part extending from a side of the first part and including a first flat surface, and a third part extending from an opposite side of the first part and including a second flat surface defining a first angle with the first flat surface, a seating surface, on which a target substrate is seated, is defined by the curved surface, the first flat surface, and the second flat surface, and a space, in which a resin is filled, is formed between the target substrate and the first part in a state, in which the target substrate is seated on the stage.

With respect to a reference line being parallel to a normal line at a central point of the first part, the first flat surface may be inclined at a first sub-angle with respect to the reference line, and the second flat surface may be inclined at a second sub-angle with respect to the reference line, the first angle may be defined as a sum of the first sub-angle and the second sub-angle, and the first angle may range from 60 degrees to 179.5 degrees.

The first sub-angle and the second sub-angle may be equal to each other.

The first part, the second part, and the third part may have an integral shape.

On a cross-section, the curved surface may have a concave shape having a first radius of curvature.

### BRIEF DESCRIPTION OF THE FIGURES

The above and other objects and features of the present disclosure will become apparent by describing in detail embodiments thereof with reference to the accompanying drawings.

FIG. 1A is a perspective view illustrating an unfolded state of a display device according to an embodiment of the present disclosure.

FIG. 1B is a perspective view illustrating an in-folding process of the display device illustrated in FIG. 1A.

FIG. 1C is a perspective view illustrating an out-folding process of the display device illustrated in FIG. 1A.

FIG. 2A is a perspective view illustrating an unfolded state of a display device according to an embodiment of the present disclosure.

FIG. 2B is a perspective view illustrating an in-folding process of the display device illustrated in FIG. 2A.

FIG. 2C is a perspective view illustrating an out-folding process of the display device illustrated in FIG. 2A.

FIG. 3 is an exploded perspective view of a display device according to an embodiment of the present disclosure.

FIG. 4 is a cross-sectional view of a display device according to an embodiment of the present disclosure.

FIG. 5A and FIG. 5B are views schematically illustrating cross-sections of a display device according to an embodiment in a folded state, respectively.

FIG. 6A is a cross-sectional view illustrating a window according to an embodiment of the present disclosure.

FIG. 6B is a cross-sectional view illustrating a portion of a window according to an embodiment of the present disclosure.

FIGS. 7A and 7B are views schematically illustrating cross-sections of one component included in a display device according to an embodiment, respectively.

FIG. 8A is a perspective view illustrating a stage that constitutes a window manufacturing apparatus according to an embodiment.

FIG. 8B is a cross-sectional view illustrating a stage that constitutes a window manufacturing apparatus according to an embodiment.

FIG. 8C is a cross-sectional view illustrating a portion of a stage that constitutes a window manufacturing apparatus according to an embodiment.

FIG. 9A is a flowchart illustrating a method for manufacturing a display device according to an embodiment of the present disclosure.

FIG. 9B is a flowchart illustrating a method for manufacturing a window according to an embodiment of the present disclosure.

FIG. 9C is a flowchart detailing an operation of forming a resin layer in a method for manufacturing a window according to an embodiment of the present disclosure.

FIGS. 10A to 10M are views illustrating some operations of a method for manufacturing a display device according to an embodiment of the present disclosure.

### DETAILED DESCRIPTION

Hereinafter, embodiments of the present disclosure will be described with reference to the drawings.

In the specification, when it is described that a component (or an area, a layer, a part, or the like) is “disposed on”, “connected to”, or “coupled to” another component, it means that the former component may be directly disposed on, connected to, or coupled to the latter component or a third component may be disposed between the components.

The same reference numerals denote the same components. Furthermore, in the drawings, thicknesses, ratios, dimensions of the components are exaggerated for an effective description of the technical contents. The term “and/or” includes one or more combinations that may be defined by the associated components.

Furthermore, in describing the various components, the terms, such as, for example, first and second may be used, but the present disclosure is not limited by the terms. The terms are simply for distinguishing the components. For example, a first component may be named a second component, and similarly the second component also may be named the first component while not departing from the scope of the present disclosure. A singular expression includes a plural expression unless an exemption is explicitly described in the context.

Furthermore, the terms, such as, for example, “under”, “below”, “on”, and “above”, are used to describe an associative relationship between the components illustrated in the drawings. The terms are relative concepts, and are described with respect to directions indicated in the drawings.

When the terms, such as, for example, “comprise” and/or “comprising”, is used in the specification, it should be understood that the terms specify presence of the above-mentioned features, numbers, steps, operations, components, parts, and/or combinations thereof, and do not exclude presence or addition of one or more other numbers, steps, operations, components, parts, and/or combinations thereof.

In the specification, the expression of “directly disposed” may mean that none of a layer, a film, an area, and a plate is added between a part, such as, for example, the layer, the film, the area, and the plate, and another part. For example, the expression of “directly disposed” may mean that the two layers or two members are disposed while an additional member, such as, for example, an adhesive member, is not used therebetween.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms, including technical and scientific terms, used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, a window according to an embodiment of the present disclosure, and a display device according to an embodiment will be described with reference to the drawings.

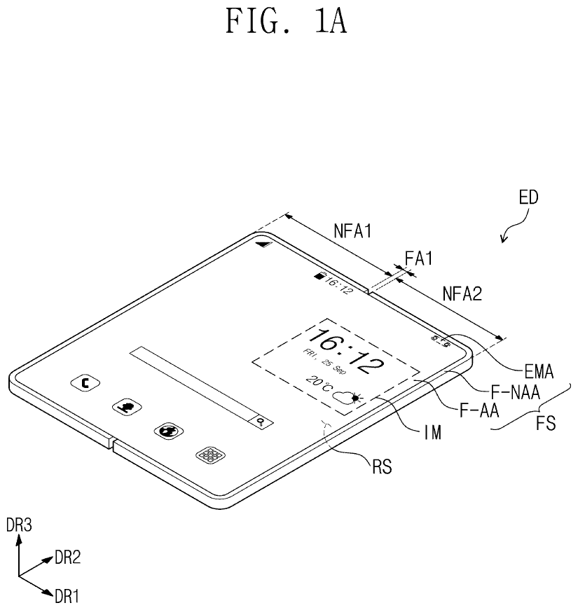

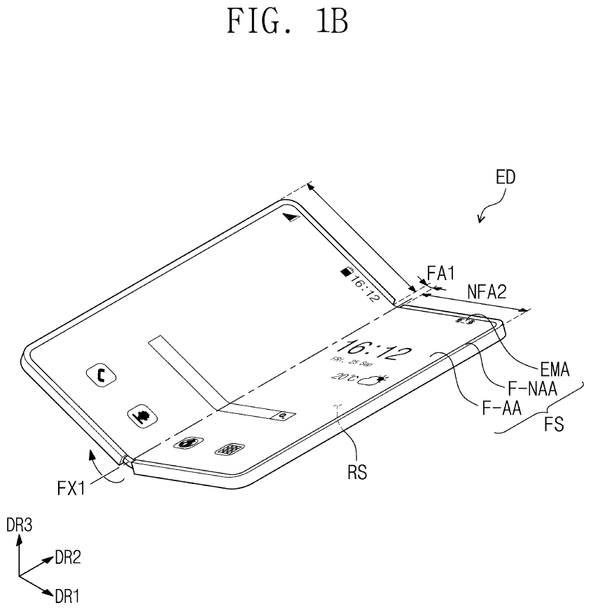

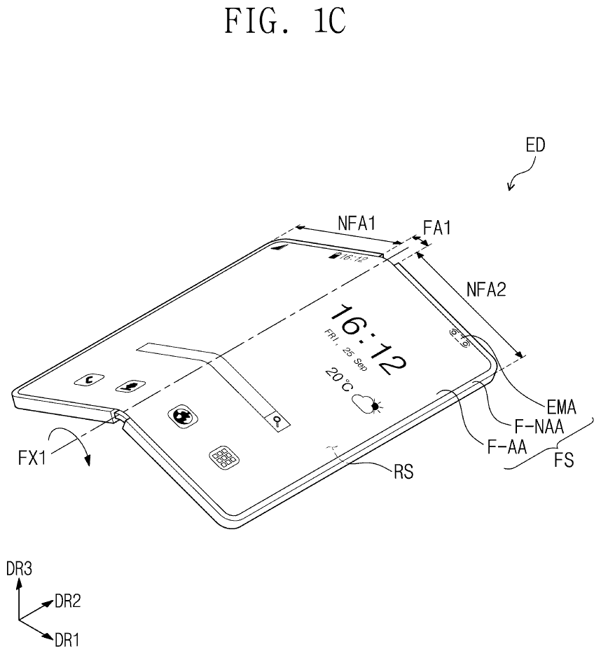

FIG. 1A is a perspective view illustrating an unfolded state of a display device according to an embodiment. FIG. 1B is a perspective view illustrating an in-folding process of the display device illustrated in FIG. 1A. FIG. 1C is a perspective view illustrating an out-folding process of the display device illustrated in FIG. 1A.

A display device ED of an embodiment may be a device that is activated according to an electric signal. For example, the display device ED may be a mobile phone, a tablet, a car navigation system, a game console, or a wearable device, but the embodiment is not limited thereto. In FIG. 1A of the specification of the present disclosure, it is illustrated by way of example that the display device ED is a mobile phone.

Referring to FIGS. 1A to 1C, the display device ED according to an embodiment may include a first display surface FS that is defined by a first direction DR1 and a second direction DR2 that crosses the first direction DR1. The display device ED may provide an image IM to the user through the first display surface FS. The display device ED of an embodiment may display an image IM toward a third direction DR3 to the first display surface FS that is parallel to each of the first direction DR1 and the second direction DR2. In the specification, a front surface (or an upper surface) and a rear surface (or a lower surface) of each component are defined with respect to a direction, in which the image IM is displayed. The front surface and the rear surface may be opposite to each other in the third direction DR3, and normal directions of the front surface and the rear surface may be parallel to the third direction DR3.

The display device ED according to an embodiment may include the first display surface FS and a second display surface RS. The first display surface FS may include an active area F-AA and a peripheral area F-NAA. The active area F-AA may include an electronic module area EMA. The second display surface RS may be defined as a surface that is opposite to at least a portion of the first display surface FS. That is, the second display surface RS may be defined as a portion of a rear surface of the display device ED.

The display device ED according to an embodiment may sense an external input that is applied from an outside. The external input may include various types of inputs that are provided from an outside of the display device ED. For example, the external input may include not only a contact by a part of the body, such as, for example, a hand of the user but also an external input (e.g., hovering) that is applied close to the display device ED at a specific distance. Furthermore, the external input may have various forms, such as, for example, a force, a pressure, a temperature, and light.

In FIG. 1A and the following drawings, the first to third directions DR1 to DR3 are illustrated, and the directions indicated by the first to third directions DR1 to DR3 described in the specification are relative concepts, and may be converted into other directions.

An active area F-AA of the display device ED may be an area that is activated according to an electric signal. The display device ED according to an embodiment may display an image IM through the active area F-AA. Furthermore, various forms of external inputs may be sensed in the active area F-AA. The peripheral area F-NAA is adjacent to the active area F-AA. The peripheral area F-NAA may have a specific color. The peripheral area F-NAA may surround the active area F-AA. Accordingly, a shape of the active area F-AA may be substantially defined by the peripheral area F-NAA. However, this is illustrated by way of example, and the peripheral area F-NAA may be disposed adjacent to a single side of the active area F-AA, or may be omitted. The display device ED according to an embodiment of the present disclosure may include active areas of various shapes, and is not limited to any one embodiment.

The display device ED may include a folding area FA1 and non-folding area NFA1 and NFA2. In an embodiment, the non-folding areas NFA1 and NFA2 may be disposed adjacent to the folding area FA1 with the folding area FA1 being interposed between the non-folding areas NFA1 and NFA2 and the folding area FA1. The display device ED of an embodiment may include a first non-folding area NFA1 and a second non-folding area NFA2 that are disposed spaced apart from each other in the first direction DR1, with the folding area FA1 being interposed between the first non-folding area NFA1 and the second non-folding area NFA2. For example, the first non-folding area NFA1 may be disposed on a side of the folding area FA1 along the first direction DR1, and the second non-folding area NFA2 may be disposed on the other side of the folding area FA1 along the first direction DR1.

Although FIGS. 1A to 1C illustrate an embodiment of the display device ED including one folding area FA1, the embodiment is not limited thereto, and a plurality of folding areas may be defined in the display device ED. For example, the display device according to an embodiment may include two or more folding areas, and the display device may also include three or more non-folding areas that are disposed, with the folding areas being interposed between the three or more non-folding areas.

Referring to FIG. 1B, the display device ED according to an embodiment may be folded with respect to a first folding axis FX1. The first folding axis FX1 may be an imaginary axis that extends in a second direction DR2, and the first folding axis FX1 may be parallel to a direction of a long side of the display device ED. The first folding axis FX1 may extend along the second direction DR2 on the first display surface FS.

The display device ED may be folded with respect to the first folding axis FX1 and may be deformed into an in-folding state, in which one area of the first display surface FS, which overlaps the first non-folding area NFA1, and an opposite area that overlaps the second non-folding area NFA2 face each other.

The display device ED according to an embodiment may have a second display surface RS that is visually recognized by the user in the in-folded state. The second display surface RS may further include an electronic module area, in which an electronic module including various components is disposed, and is not limited to any one embodiment.

Referring to FIG. 1C, the display device ED according to an embodiment may be folded with respect to the first folding axis FX1 and may be deformed into an out-folding state, in which one area of the second display surface RS, which overlaps the first non-folding area NFA1, and an opposite area that overlaps the second non-folding area NFA2 face each other.

However, the embodiment is not limited thereto, and may be folded with respect to a plurality of folding axes to be folded such that portions of the first display surface FS and the second display surface RS face each other, and the number of the folding axes and the number of the non-folding areas according to the folding axes are not particularly limited.

Various electronic modules may be disposed in the electronic module area EMA. For example, the electronic module may include at least one of a camera, a speaker, a light detection sensor, and a heat detection sensor. The electronic module area EMA may sense an external subject that is received through the first or second display surface FS or RS or provide a sound signal, such as, for example, a voice output to the outside through the first or second display surface FS or RS. The electronic module may include a plurality of components, and is not limited to any one embodiment.

The electronic module area EMA may be surrounded by the active area F-AA and the peripheral area F-NAA. However, embodiments of the present disclosure are not limited thereto, and the electronic module area EMA may be disposed in the active area F-AA, and is not limited to any one embodiment.

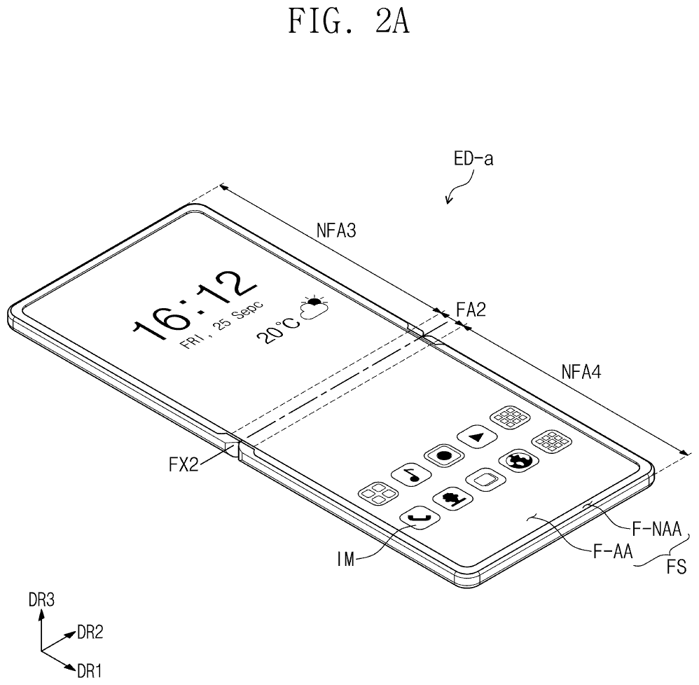

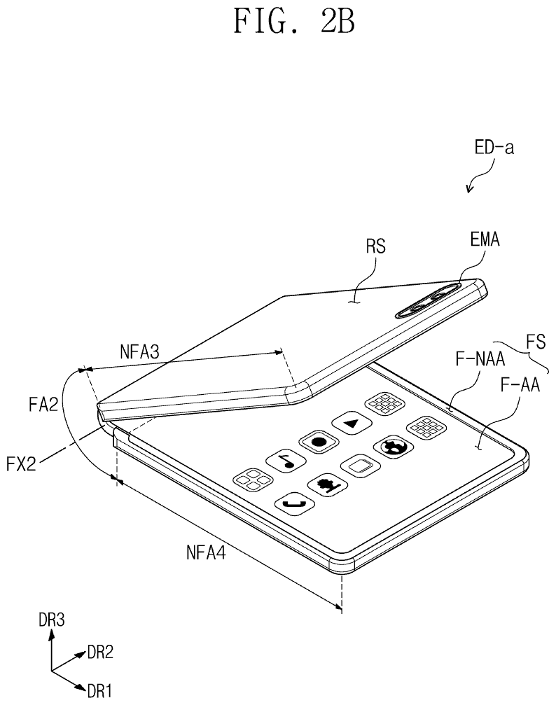

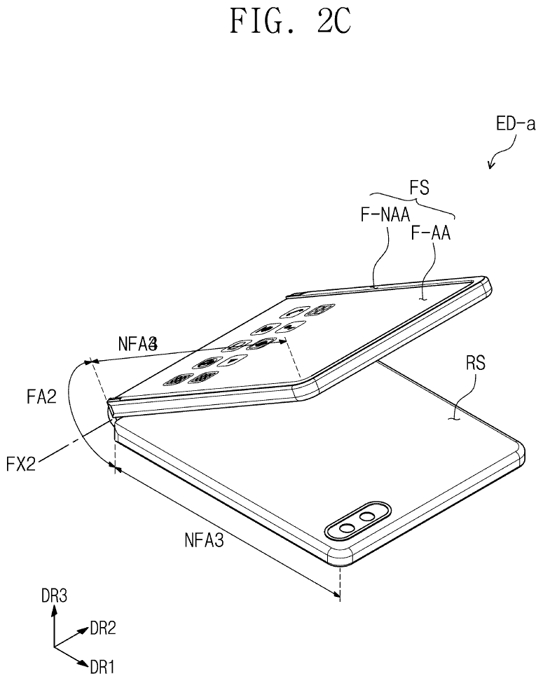

FIG. 2A is a perspective view illustrating an unfolded state of a display device according to an embodiment. FIG. 2B is a perspective view illustrating an in-folding process of the display device illustrated in FIG. 2A. FIG. 2C is a perspective view illustrating an out-folding process of the display device illustrated in FIG. 2A.

A display device ED-a of an embodiment may be folded with respect to a second folding axis FX2 that extends in a direction that is parallel to the second direction DR2. In FIG. 2B, a case, in which an extension direction of the second folding axis FX2 is parallel to an extension direction of a short side of the display device ED-a, is illustrated. However, embodiments of the present disclosure are not limited thereto.

The display device ED-a according to an embodiment may include at least one folding area FA2, and non-folding areas NFA3 and NFA4 that are adjacent to the folding area FA2. The non-folding areas NFA3 and NFA4 may be disposed such that the non-folding areas NFA3 and NFA4 are spaced apart from each other with the folding area FA2 being interposed between the non-folding areas NFA3 and NFA4.

The folding area FA2 has a specific curvature and a specific radius of curvature. In an embodiment, the first non-folding area NFA3 and the second non-folding area NFA4 may face each other, and the display device ED-a may be in-folded such that the display surface FS is not exposed to the outside. Furthermore, referring to FIG. 2C, in an embodiment, the display device ED-a may be out-folded such that the first display surface FS is exposed to the outside.

The display device ED-a according to an embodiment may include a second display surface RS, and the second display surface RS may be defined as a surface that faces at least a portion of the first display surface FS. The second display surface RS may include an electronic module area EMA, in which an electronic module including various components are disposed. Furthermore, an image or a video may be displayed on at least a portion of the second display surface RS.

In some embodiments, the display device ED-a may be configured such that the first display surface FS is visually recognized by the user in an unfolded state, and the second display surface RS is visually recognized by the user in an in-folded state.

In an embodiment, the display device ED and ED-a may be configured such that an in-folding operation or an out-folding operation is mutually repeated from an unfolding operation, but the embodiment is not limited thereto. In an embodiment, the display device ED and ED-a may be configured such that any one of an unfolding operation, an in-folding operation, and an out-folding operation is selected. Furthermore, when a plurality of folding areas are included, a folding direction of at least one of the plurality of folding areas may be different from folding directions of the remaining folding areas. In an example in which two folding areas are included, two non-folding areas with one folding area being interposed between the two non-folding areas may be folded through an in-folding operation, and two non-folding areas with the remaining one folding area being interposed between the two non-folding areas may be folded through an out-folding operation.

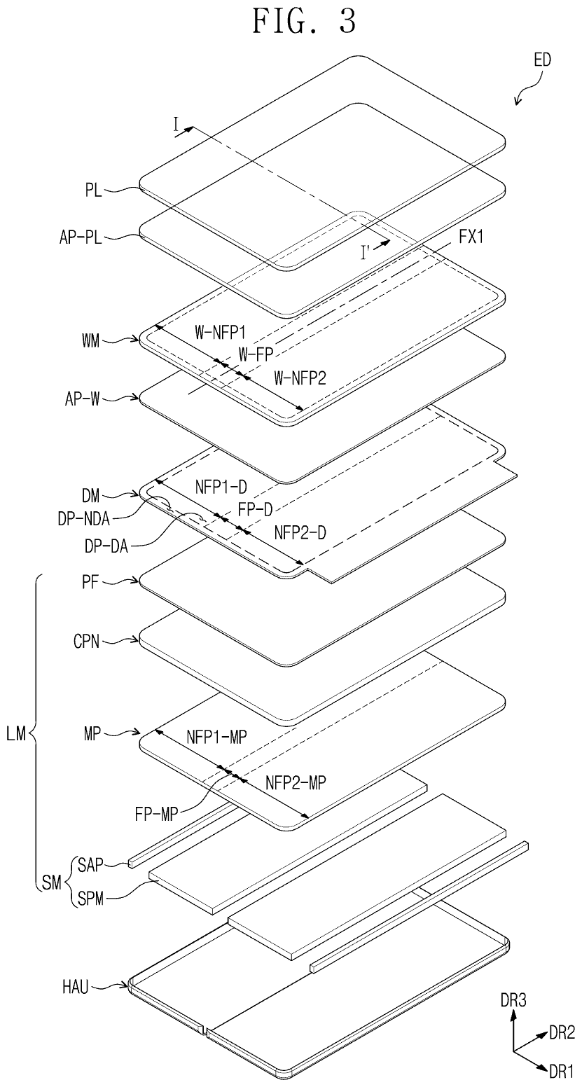

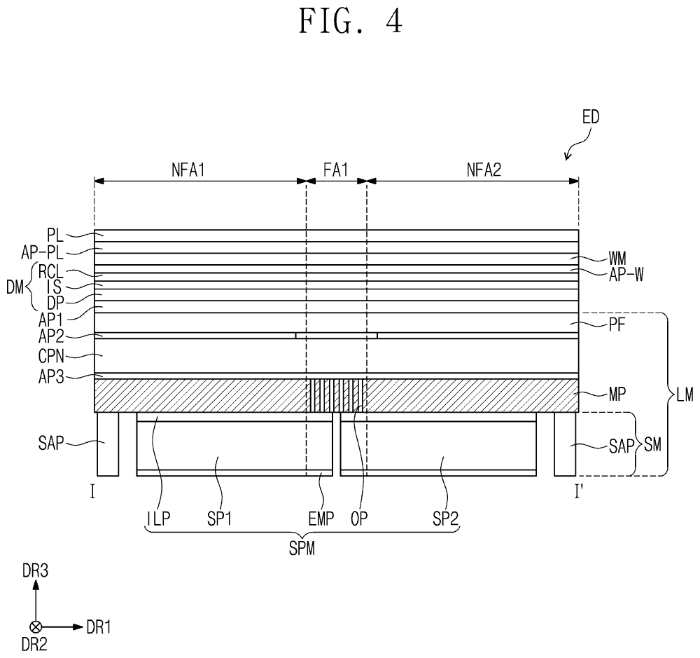

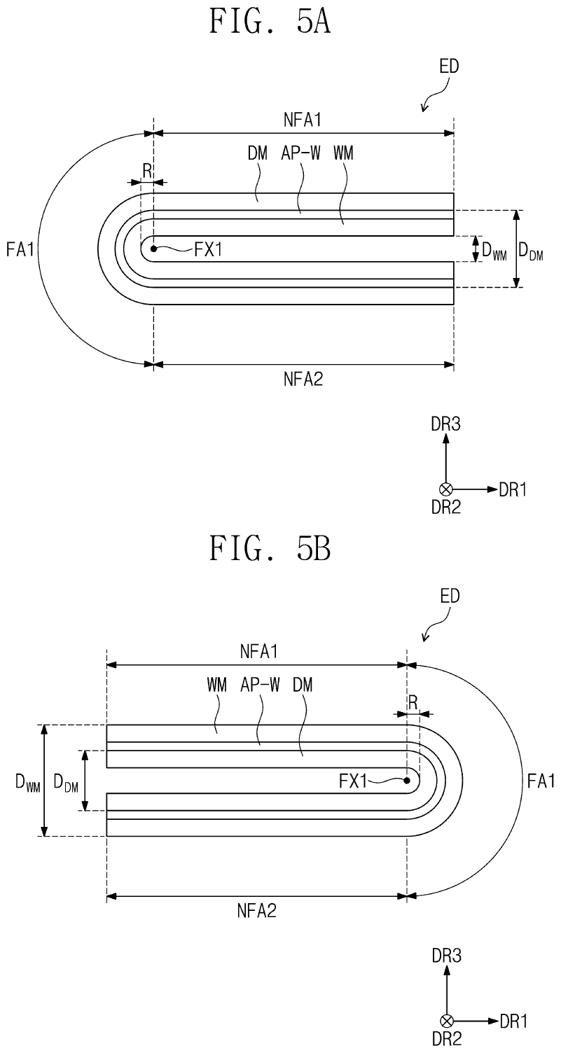

FIG. 3 is an exploded perspective view of a display device according to an embodiment, and FIG. 4 is a cross-sectional view of the display device according to an embodiment. FIG. 3 illustrates, by way of example, an exploded perspective view of a display device according to an embodiment illustrated in FIG. 1A. FIG. 4 is a cross-sectional view illustrating a part corresponding to line I-I′ of FIG. 3.

In FIGS. 3 and 4, and the like below, it is illustrated that the folding axis FX1 of the display device ED illustrated in FIG. 1A, and the like are parallel to the long side of the display device ED, but the embodiment is not limited thereto, and the contents described with reference to the drawings below may also be applied to the case, in which the folding axis FX2 is parallel to the short side of the display device, as illustrated in FIG. 2A, and the like.

Referring to FIGS. 3 and 4, the display device ED of an embodiment may include a display module DM, and a window WM that is disposed on an upper side of the display module DM. Furthermore, the display device ED of an embodiment may further include a lower module LM that is disposed on a lower side of the display module DM.

The display device ED of an embodiment may further include a window adhesion layer AP-W that is disposed between the display module DM and the window WM, and may further include a protective film PL and a protective adhesion layer AP-PL that are disposed on an upper side of the window WM. In the display device ED of an embodiment, the protective film PL and the protective adhesion layer AP-PL may be omitted. In an example in which the protective film PL and the protective adhesion layer AP-PL are omitted, the window WM may be an uppermost surface of the display device ED.

The lower module LM may include a support plate MP that is disposed on a lower side of the display module DM. The lower module LM may also be referred to as a support member.

The display device ED may include a housing HAU that accommodates the display module DM and the lower module LM. The housing HAU may be coupled to the window WM. Although not illustrated, the housing HAU may further include a hinge structure for facilitating folding or bending. The window WM may be a cover window that is disposed on the display module DM.

The display device ED of an embodiment may include a window adhesion layer AP-W that is disposed between the display module DM and the window WM. The window adhesion layer AP-W may be an optically clear adhesive film OCA or an optically clear adhesive resin layer OCR. In some embodiments, the window adhesion layer AP-W may be omitted.

The window WM may cover an entire upper surface of the display module DM. The window WM may have a shape corresponding to a shape of the display module DM. The window WM may include glass, and may be used as a cover window of the display device.

The window WM may include a folding part W-FP and non-folding parts W-NFP1 and W-NFP2. A first non-folding part W-NFP1 and a second non-folding part W-NFP2 of the window WM may be spaced apart from each other in the first direction DR1 with the folding part W-FP being interposed between the first non-folding part W-NFP1 and the second non-folding part W-NFP2. The folding part W-FP may be a part corresponding to the folding area FA1 (FIG. 1A), and the non-folding parts W-NFP1 and W-NFP2 may be parts corresponding to the non-folding areas NFA1 and NFA2 (FIG. 1A).

In an embodiment, in the window WM, a plurality of glass substrates have a structure of joining glass. Each of the joined glass substrates may be a tempered glass substrate. Furthermore, each of the joined glass substrates may be an ultra-thin tempered glass substrate (ultra-thin glass). The window WM according to an embodiment will be described in more detail later.

The display module DM may display an image according to an electric signal and transmit/receive information on an external input. The display module DM may include a display area DP-DA and a non-display area DP-NDA. The display area DP-DA may be defined as an area that outputs an image provided by the display module DM.

The non-display area DP-NDA is adjacent to the display area DP-DA. For example, the non-display area DP-NDA may surround the display area DP-DA. However, this is an example, and the non-display area DP-NDA may be defined in various shapes, and is not limited to any one embodiment. According to an embodiment, the display area DP-DA of the display module DM may correspond to at least a portion of the active area F-AA (FIG. 1A).

In an embodiment, the display module DM includes a display panel DP. The display panel DP may be a light emitting display panel, and is not particularly limited. For example, the display panel DP may be an organic light emitting display panel or an inorganic light emitting display panel. The light emitting layer of the organic light emitting display panel may include an organic light emitting material. The light emitting layer of the inorganic light emitting display panel may include quantum dots and quantum rods, and the like.

The display module DM may further include an input sensor IS. The input sensor IS may be disposed directly on the display panel DP. The input sensor IS may include a plurality of sensing electrodes. The input sensor IS may sense an external input in a self-cap method or a mutual-cap method. The input sensor IS may also sense an input through an active type input device.

The input sensor IS may be formed directly on the display panel DP through a continuous process during the manufacturing of the display panel DP. However, the embodiment is not limited thereto, and the input sensor IS may be manufactured as a separate panel from the display panel DP and be attached to the display panel DP by an adhesion layer (not illustrated).

Furthermore, the display module DM may further include an optical layer RCL. The optical layer RCL may have a function of reducing reflection by external light. For example, the optical layer RCL may include a polarizing layer or a color filter layer. However, the embodiment is not limited thereto, and the optical layer RCL may include optical members for improving a display quality of the display device ED.

In an embodiment, the optical layer RCL may be disposed directly on the input sensor IS. Furthermore, when the input sensor IS is omitted in the display module DM, the optical layer RCL may be disposed directly on the display panel DP. However, the embodiment is not limited thereto, and the optical layer RCL may be disposed on the display panel DP or the input sensor IS by using a separate adhesion member.

The display module DM may include a folding display part FP-D and non-folding display parts NFP1-D and NFP2-D. The folding display part FP-D may be a part corresponding to the folding area FA1 (FIG. 1A), and the non-folding display parts NFP1-D and NFP2-D may be parts corresponding to the non-folding areas NFA1 and NFA2 (FIG. 1A).

The folding display part FP-D may correspond to a part that is folded or bent with respect to the first folding axis FX1 (FIGS. 1B and 1C). The display module DM includes a first non-folding display part NFP1-D and a second non-folding display part NFP2-D, and the first non-folding display part NFP1-D and the second non-folding display part NFP2-D may be spaced apart from each other with the folding display part FP-D being interposed between the first non-folding display part NFP1-D and the second non-folding display part NFP2-D.

In the display device ED according to an embodiment, the lower module LM may include a support plate MP. Furthermore, in an embodiment, the lower module LM may further include at least one of a support module SM, a protective layer PF, and an impact absorbing layer CPN. For example, the display device ED according to an embodiment may include a support plate MP that is disposed on a lower side of the display module DM, the protective layer PF and the impact absorbing layer CPN that are disposed between the support plate MP and the display module DM, and the support module SM that is disposed on a lower side of the support plate MP.

In an embodiment, the support plate MP may be disposed on a lower side of the display module DM. The support plate MP may include a folding support part FP-MP and non-folding support parts NFP1-MP and NFP2-MP. The first non-folding support part NFP1-MP and the second non-folding support part NFP2-MP of the support plate MP may be spaced apart from each other with the folding support part FP-MP being interposed between the first non-folding support part NFP1-MP and the second non-folding support part NFP2-MP. The folding support part FP-MP may be a part corresponding to the folding area FA1 (FIG. 1A), and the non-folding support parts NFP1-MP and NFP2-MP may be parts corresponding to the non-folding areas NFA1 and NFA2 (FIG. 1A).

Referring to FIGS. 3 and 4, the protective layer PF may be disposed between the display module DM and the support plate MP. The protective layer PF may be a layer that is disposed on a lower side of the display module DM to protect a rear surface of the display module DM. The protective layer PF may overlap the entire display module DM. The protective layer PF may include a polymer material. For example, the protective layer PF may be a polyimide film or a polyethylene terephthalate film. However, this is an example and a material of the protective layer PF is not limited thereto.

The display device ED according to an embodiment may include the support module SM. The support module SM may include a support part SPM and a filling part SAP. The support part SPM may be a part that overlaps most areas of the display module DM. The filling part SAP may be a portion that is disposed on an outside of the support part SPM and overlaps an outskirt of the display module DM.

The support module SM may include support layers SP1 and SP2. The support layers SP1 and SP2 may include a first sub-support layer SP1 and a second sub-support layer SP2 that are spaced apart from each other in the first direction DR1. The first sub-support layer SP1 and the second sub-support layer SP2 may be spaced apart from each other at a portion corresponding to the first folding axis FX1 (FIG. 1B and FIG. 1C). The support layers SP1 and SP2 may be spaced apart from each other in the folding area FA1 and be provided as a first sub-support layer SP1 and a second sub-support layer SP2 whereby the folding or bending characteristics of the display device ED may be improved. In some embodiments, although not illustrated, the support layers SP1 and SP2 may include configurations of a cushion layer (not illustrated) and a lower support plate (not illustrated) that are laminated in a thickness direction.

The lower support plate (not illustrated) may include a metal material or a polymeric material. For example, the lower support plate may be formed while including stainless steel, aluminum, copper, or an alloy thereof.

The cushion layer (not illustrated) may prevent the support plate MP from being pressed and deformed due to an external impact and a force. The cushion layer (not illustrated) may include an elastic polymer, such as, for example, a sponge, foam, or urethane resin. Furthermore, the cushion layer (not illustrated) may be formed while including at least one of an acrylic polymer, a urethane polymer, a silicone polymer, and an imide polymer. However, embodiments of the present disclosure are not limited thereto. The cushion layer (not illustrated) may be disposed on a lower side of the support plate MP or a lower side of the lower support plate (not illustrated).

Furthermore, the support module SM may further include at least one of a shield layer EMP and an inter-layer joining layer ILP. The shield layer EMP may be an electromagnetic shield layer or a heat dissipating layer. Furthermore, the shield layer EMP may function as a joining layer. The support module SM and the housing HAU may be joined to each other by using a shield layer EMP. The shield layer EMP may be disposed on a lower side of the support layers SP1 and SP2.

The support module SM may further include an inter-layer joining layer ILP that is disposed on an upper side of the support layers SP1 and SP2. The inter-layer joining layer ILP may join the support plate MP and the support module SM. The inter-layer joining layer ILP may be provided in the form of a joining resin layer or an adhesion tape. For example, the inter-layer joining layer ILP may be one, of which a portion that overlaps the folding display part FP-D is removed. However, the embodiment is not limited thereto, and the inter-layer joining layer ILP may overlap the entire folding display part FP-D.

The filling part SAP may be disposed on an outskirt of the support layers SP1 and SP2. The filling part SAP may be disposed between the support plate MP and the housing HAU. The filling part SAP may fill a space between the support plate MP and the housing HAU, and may fix the support plate MP.

Referring to FIGS. 3 and 4, the display device ED of an embodiment may include an impact absorbing layer CPN in the lower module LM. The impact absorbing layer CPN may function as a thickness compensation layer that compensates for the thickness of the lower side of the display module DM, or as a support layer that supports the display module DM. In some aspects, unlike the illustration, the impact absorbing layer CPN in an embodiment may be omitted.

The combination of the components included in the lower module LM in the display device ED of an embodiment may vary depending on a size, a shape, or operation characteristics of the display device ED.

Furthermore, the display device ED of an embodiment may further include at least one adhesion layer AP1, AP2, and AP3. For example, the first adhesion layer AP1 may be disposed between the display module DM and the protective layer PF, the second adhesion layer AP2 may be disposed between the protective layer PF and the impact absorbing layer CPN, and the third adhesion layer AP3 may be disposed between the support plate MP and the impact absorbing layer CPN. At least one adhesion layer AP1, AP2, and AP3 may be an optically clear adhesive film OCA or an optically clear adhesive resin layer OCR. However, the embodiment is not limited thereto, and at least one adhesion layer AP1, AP2, and AP3 may be an adhesion layer having a low transmittance of 80% or less.

The display device ED of an embodiment may further include a protective film PL that is disposed on an upper side of the window WM. The protective film PL may be disposed on an upper side of the window WM to protect the window WM from an external environment. However, in the display device ED of an embodiment, the protective film PL may be omitted, and the window WM may be an uppermost surface of the display device ED.

A protective adhesion layer AP-PL may be further disposed between the window WM and the protective film PL. The protective adhesion layer AP-PL may be an optically clear adhesive layer. In an example in which the display device ED of an embodiment includes the protective film PL, the protective film PL may be a layer that is exposed to an outside of the display device ED.

The protective film PL may have optical properties having a transmittance of 90% or more in a visual ray area and a haze value of less than 1%. The protective film PL may include a polymer film. Furthermore, the protective film PL may further include a base layer of a polymer film, and a functional layer, such as, for example, a hard coating layer, an anti-fingerprint coating layer, an anti-static coating layer, and the like on the base layer. In some aspects, the protective film PL used in the display device ED of an embodiment may have flexibility.

FIG. 5A and FIG. 5B are views schematically illustrating cross-sections of the display device ED according to an embodiment in a folded state, respectively. In FIG. 5A and FIG. 5B, the configurations of the display module DM, the window adhesion layer AP-W, and the window WM among the display device ED are briefly illustrated.

The drawing illustrated in FIG. 5A illustrates a cross-section of the in-folded state, and in an embodiment of a display device ED, a distance DWM between upper surfaces of facing windows WM in the folded state may be smaller than a distance DDM between upper surfaces of facing display modules DM. In the display device ED of an embodiment, a radius “R” of curvature of the in-folded folding area FA1 with respect to a first folding axis FX1 may be about 1 mm or less. That is, because the window WM of an embodiment, which will be described later, includes a glass substrate, in which a recessed part is defined in correspondence to the folding area, a bending limit radius of the radius “R” of curvature of the folding area FA1 may be reduced to 1 mm or less. However, the embodiment is not limited thereto, and a radius “R” of curvature of the folding area FA1 may be greater than 1 mm.

The drawing illustrated in FIG. 5B illustrates a cross-section of the out-folded state, and in an embodiment of a display device ED, a distance DDM between upper surfaces of the facing display modules DMs in the folded state may be smaller than a distance DWM between upper surfaces of the facing windows WMs. In the display device ED of an embodiment, a radius “R” of curvature of the out-folded folding area FA1 with respect to the first folding axis FX1 may be 1 mm or less. That is, because the window WM of an embodiment, which will be described later, includes a glass substrate, in which a recessed part corresponding to the folding area is defined, a bending limit radius of the radius “R” of curvature of the folding area FA1 may be reduced to 1 mm or less. However, the embodiment is not limited thereto, and a radius “R” of curvature of the folding area FA1 may be greater than 1 mm.

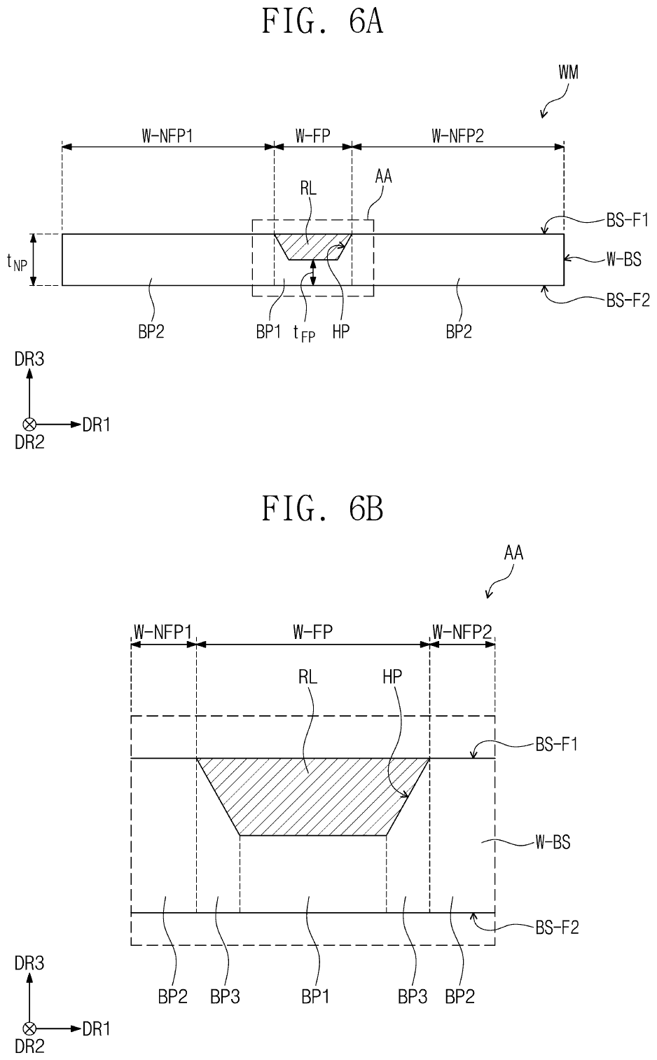

FIG. 6A is a cross-sectional view illustrating a window according to an embodiment. FIG. 6B is a cross-sectional view illustrating a portion of a window according to an embodiment. FIG. 6B illustrates, by way of example, a cross-section of the window WM according to an embodiment as a part corresponding to the area AA of FIG. 6A.

Referring to FIGS. 6A and 6B, the window WM of an embodiment may include a base substrate W-BS, in which a recessed part HP is defined on at least one surface thereof, and a resin layer RL that is disposed in the recessed part HP.

The base substrate W-BS of an embodiment may include a first non-folding part W-NFP1, a second non-folding part W-NFP2, and a folding part W-FP that is disposed between the first non-folding part W-NFP1 and the second non-folding part W-NFP2. The first non-folding part W-NFP1 and the second non-folding part W-NFP2 of the base substrate W-BS may be spaced apart from each other in the first direction DR1 with the folding part W-FP being interposed between the first non-folding part W-NFP1 and the second non-folding part W-NFP2. The folding part W-FP may be a part corresponding to the folding area FA1 (FIG. 1A), and the non-folding parts W-NFP1 and W-NFP2 may be parts corresponding to the non-folding areas NFA1 and NFA2 (see FIG. 1A). In the specification, “an area/part and another area/part correspond to each other” means overlapping, and is not limited to the same area.

In the window WM of an embodiment, the base substrate W-BS may be a tempered glass substrate. The base substrate W-BS may be a glass substrate that is chemically tempered or thermally tempered.

In the window WM of an embodiment, the base substrate W-BS may include a first base surface BS-F1 and a second base surface BS-F2 that face each other with respect to a third direction DR3. In the window WM of an embodiment, a recessed part HP may be defined on at least one of the first base surface BS-F1 and the second base surface BS-F2. For example, the recessed part HP may be defined on the first base surface BS-F1 of the base substrate W-BS. However, the embodiment is not limited thereto, and unlike as the illustration of FIG. 6A, the recessed part HP may be defined on each of the first base surface BS-F1 and the second base surface BS-F2 of the base substrate W-BS.

In the window WM of an embodiment, the recessed part HP may be defined on the first base surface BS-F1 of the base substrate W-BS. The recessed part HP may be a part that is formed in correspondence to the folding part W-FP. That is, the recessed part HP may be defined on the first base surface BS-F1 such that the recessed part HP overlaps the folding part W-FP. The recessed part HP may be defined on the first base surface BS-F1 of the base substrate W-BS, and the recessed part HP may be defined such that the recessed part HP is concavely recessed from the first base surface BS-F1 of the base substrate W-BS toward the second base surface BS-F2.

The resin layer RL may be disposed in the recessed part HP defined in the folding part W-FP of the window WM. The resin layer RL may be disposed while filling the recessed part HP. The resin layer RL may include a material having a refractive index value that matches with a refractive index of the base substrate W-BS. The recessed part HP defined in the folding part W-FP of the window WM may be filled with the resin layer RL whereby degradation of a quality due to the recessed part HP may be improved and a mechanical strength of the folding part W-FP may be improved.

The recessed part HP may be defined on the first base surface BS-F1 of the base substrate W-BS through a slimming process. A physical polishing method or a chemical polishing method may be used in the slimming process. Furthermore, in an embodiment, the recessed part HP may be defined by slimming one surface of the base substrate W-BS by using a laser.

In an embodiment, the base substrate W-BS may have a thickness thinner at a portion, at which the recessed part HP is defined, than at the remaining portions. That is, in an embodiment, a first average thickness tFp of a part of the base substrate W-BS, which corresponds to the folding part W-FP, may be smaller than a second average thickness tNp of parts corresponding to the non-folding parts W-NFP1 and W-NFP2. The window WM of an embodiment may exhibit good folding characteristics as the window WM includes the base substrate W-BS, in which the thickness of the part corresponding to the folding part W-FP is relatively smaller than the thickness of the parts corresponding to the non-folding parts W-NFP1 and W-NFP2.

Referring to FIG. 6B, the base substrate W-BS may include a first base part BP1 corresponding to the folding part W-FP, a second base part BP2 corresponding to the non-folding parts W-NFP1 and W-NFP2, and a third base part BP3 that is disposed between the first base part BP1 and the second base part BP2. The third base part BP3 may be a part, of which a thickness increases in a direction from the first base part BP1 to the second base part BP2. In an embodiment, an average thickness of the first base part BP1 may be smaller than an average thickness of the second base part BP2.

In an embodiment, the first base part BP1 and the third base part BP3 may be parts corresponding to the folding part W-FP. In the base substrate W-BS, the first base part BP1 may correspond to a flat part, in which the first base surface BS-F1 is parallel to the second base surface BS-F2. The third base part BP3 may correspond to a part, in which the first base surface BS-F1 is an inclined surface. In the base substrate W-BS, the recessed part HP formed on the first base surface BS-F1 that is adjacent to the resin layer RL may be defined by the first base part BP1 and the third base part BP3. As described herein, the resin layer RL may be filled in the recessed part HP. The resin layer RL may contact the first base part BP1 and the third base part BP3.

The first base surface BS-F1 corresponding to the third base part BP3 on a cross-section that is parallel to a plane defined by the first direction DR1 and the third direction DR3 may have a straight line shape that connects the first base part BP1 and the first base surface BS-F1 corresponding to the second base part BP2. In an embodiment, the recessed part HP may be defined by the first base surface BS-F1 corresponding to the first base part BP1 and the first base surface BS-F1 corresponding to the third base part BP3. However, the embodiment is not limited thereto, and unlike the illustration of FIG. 6B, one surface of the third base part BP3, which defines the recessed part HP, may have a curved surface shape.

In some aspects, in an embodiment, a shape of the recessed part HP defined in the base substrate W-BS is not limited to that illustrated in FIGS. 6A and 6B. Various modifications may be made by adjusting thicknesses of the first base part BP1 and the second base part BP2, an inclination angle of the third base part BP3, or the like.

The resin layer RL may be a filling layer that fills the recessed part HP. The resin layer RL may be disposed to overlap the folding part W-FP. The resin layer RL may not overlap the non-folding parts W-NFP1 and W-NFP2. The resin layer RL may be disposed on one surface of the base substrate W-BS, which corresponds to the folding part W-FP. The resin layer RL may be disposed on one surface of the base substrate W-BS, on which the recessed part HP is defined, and may not be disposed on one surface of the base substrate W-BS, on which the recessed part HP is not defined.

The resin layer RL may be a layer formed of an organic material. The resin layer RL may include a siloxane-based compound, an acrylate-based compound, a urethane-based compound, or an epoxy-based compound. The resin layer RL may be a layer formed of a polymeric material. However, the embodiment is not limited thereto, and the resin layer RL may further include an inorganic material. The resin layer RL included in the window WM may be optically transparent. Various materials may be included to increase a strength of the resin layer RL in a range, in which the optical characteristics of the resin layer RL are maintained.

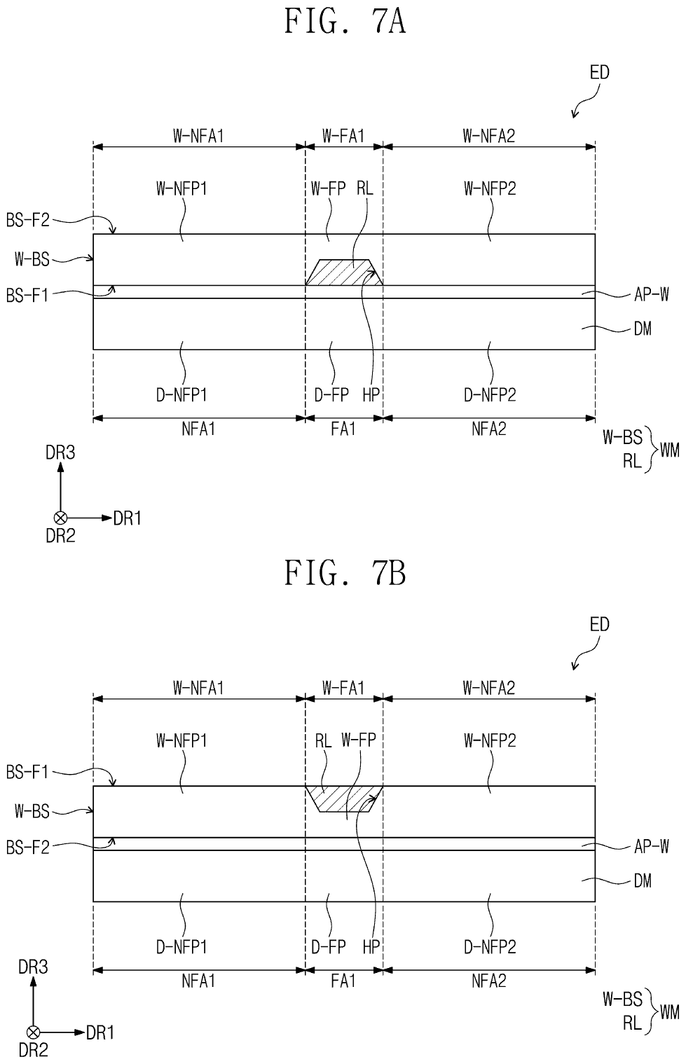

FIG. 7A and FIG. 7B are schematic views of cross-sections of a component included in a display device ED of an embodiment, respectively. In FIG. 7A and FIG. 7B, the components of the display module DM, the window adhesion layer AP-W, and the window WM of the display device ED are briefly illustrated.

Referring to FIG. 7A, in the window WM of an embodiment, the first base surface BS-F1 of the base substrate W-BS may be closer to the display module DM than the second base surface BS-F2. In the window WM of an embodiment, the base substrate W-BS may be disposed such that the first base surface BS-F1, in which the recessed part HP is defined, is closer to the display module DM than the second base surface BS-F2. The first base surface BS-F1 may be disposed adjacent to the display module DM. The second base surface BS-F2 may be disposed such that the second base surface BS-F2 faces the first base surface BS-F1 in the third direction DR3 and is spaced apart from the display module DM. In the display device ED of an embodiment, the second base surface BS-F2 may be exposed to the outside. Furthermore, in the display device ED of an embodiment, the resin layer RL may be disposed adjacent to the display module DM.

When the display device ED of an embodiment illustrated in FIG. 7A is in-folded as in the operation of FIG. 1B, a portion of the second base surface BS-F2 of the base substrate W-BS corresponding to the first non-folding part W-NFP1 and a portion the second base surface BS-F2 of the base substrate W-BS corresponding to the second non-folding part W-NFP2 may be folded such that the portions of the second base surface BS-F2 face each other adjacently to each other. Furthermore, when the display device ED of an embodiment illustrated in FIG. 7A is out-folded as in the operation of FIG. 1C, the second base surface BS-F2 of the base substrate W-BS corresponding to the first non-folding part W-NFP1 and the second base surface BS-F2 of the base substrate W-BS corresponding to the second non-folding part W-NFP2 may be exposed to the outside.

The display device ED illustrated in FIG. 7B corresponds to a display device in which a disposition direction of the window WM is different, compared to the display device ED illustrated in FIG. 7A. The display device ED illustrated in FIG. 7B corresponds to one, in which the second base surface BS-F2 of the base substrate W-BS is disposed closer to the display module DM than the first base surface BS-F1, compared to the display device ED illustrated in FIG. 7A.

Referring to FIG. 7B, in the window WM of an embodiment, the second base surface BS-F2 of the base substrate W-BS may be closer to the display module DM than the first base surface BS-F1. In the window WM of an embodiment, the base substrate W-BS may be disposed such that the second base surface BS-F2, on which the recessed part HP is not defined, is closer to the display module DM than the first base surface BS-F1, on which the recessed part HP is defined. The second base surface BS-F2 may be disposed adjacent to the display module DM. The first base surface BS-F1 may be disposed such that the first base surface BS-F1 faces the second base surface BS-F2 in the third direction DR3 and is spaced apart from the display module DM. Furthermore, in the display device ED of an embodiment, the resin layer RL may be disposed spaced apart from the display module DM.

In an embodiment of the display device ED illustrated in FIG. 7B, the resin layer RL may be exposed to the outside. However, the embodiment is not limited thereto, and the window WM of an embodiment may further include an additional protective layer that is disposed on the first base surface BS-F1 of the base substrate W-BS. In this case, the additional protective layer may be disposed on the first base surface BS-F1 of the base substrate W-BS and the resin layer RL. The resin layer RL may be disposed between the base substrate W-BS and the additional protective layer. The additional protective layer may overlap all of the first non-folding part W-NFP1, the folding part W-FP, and the second non-folding part W-NFP2 of the base substrate W-BS.

When the display device ED of an embodiment illustrated in FIG. 7B is in-folded as in the operation of FIG. 1B, a portion of the first base surface BS-F1 of the base substrate W-BS corresponding to the first non-folding part W-NFP1 and a portion of the first base surface BS-F1 of the base substrate W-BS corresponding to the second non-folding part W-NFP2 may be folded such that the portions face each other adjacently to each other. In some aspects, when the display device ED of an embodiment illustrated in FIG. 7B is out-folded as in the operation of FIG. 1C, the first base surface BS-F1 of the base substrate W-BS corresponding to the first non-folding part W-NFP1 and the first base surface BS-F1 of the base substrate W-BS corresponding to the second non-folding part W-NFP2 may be exposed to the outside.

Referring to FIGS. 7A and 7B, in the display device ED of an embodiment, the window WM may include a first window non-folding area W-NFA1, a second window non-folding area W-NFA2, and a window folding area W-FA1 that is disposed between the first window non-folding area W-NFA1 and the second window non-folding area W-NFA2. The first window non-folding area W-NFA1 and the second window non-folding area W-NFA2 may be spaced apart from each other in the first direction DR1 with the window folding area W-FA1 being interposed between the first window non-folding area W-NFA1 and the second window non-folding area W-NFA2. The window folding area W-FA1 may be a part corresponding to the folding area FA1 of the display device ED, the first window non-folding area W-NFA1 may be a part corresponding to the first non-folding area NFA1 of the display device ED, and the second window non-folding area W-NFA2 may be a part corresponding to the second non-folding area NFA2 of the display device ED.

In the window WM of an embodiment, the window folding area W-FA1 may be an area that overlaps the folding axis FX1 (see FIGS. 1B and 1C). Stress may occur in the window folding area W-FA1 due to the folding operation. Because the window WM is also folded due to the folding operation of the display device ED, a part of the window WM, which overlaps the window folding area W-FA1, may be easily deformed due to the folding stress. In the window WM of an embodiment, a shape of the window folding area W-FA1 in the unfolded state and a shape of the window folding area W-FA1 in the folded state may be substantially different, and thus, the window folding area W-FA1 may be easily deformed due to stress.

When the display device ED of an embodiment illustrated in FIG. 7A is in-folded as in the operation of FIG. 1B, tensile stress may be provided to the resin layer RL that overlaps the window folding area W-FA1. Furthermore, when the display device ED of an embodiment illustrated in FIG. 7A is out-folded as in the operation of FIG. 1C, compressive stress may be provided to the resin layer RL that overlaps the window folding area W-FA1. In an example in which tensile stress is provided to the resin layer RL in the in-folded state, the resin layer RL may be ruptured due to the tensile stress provided during the folding operation when an elongation of the resin layer RL is not sufficient

Furthermore, when the display device ED of an embodiment illustrated in FIG. 7BA is in-folded as in the operation of FIG. 1B, compressive stress may be provided to the resin layer RL that overlaps the window folding area W-FA1. Furthermore, when the display device ED of an embodiment illustrated in FIG. 7B is out-folded as in the operation of FIG. 1C, tensile stress may be provided to the resin layer RL that overlaps the window folding area W-FA1. In an example in which tensile stress is provided to the resin layer RL in the out-folded state, the resin layer RL may be ruptured due to the tensile stress provided during the folding operation when an elongation of the resin layer RL is not sufficient

According to the method for manufacturing a window according to the present disclosure, after a resin is provided to the recessed part after the base substrate, in which the recessed part is defined, is bent at a specific angle, the resin is cured, which may alleviate the tensile stress provided to the resin layer during folding. Because the resin layer is formed in a state, in which the base substrate is bent at a specific angle, the tensile stress that acts on the resin layer during folding of the window may be alleviated. Accordingly, the folding characteristics of the window may be improved, and damage due to the repeated folding operations of the display device may be prevented. Furthermore, a process reliability may be improved by using the curved stage to maintain the bending state of the base substrate during the resin layer forming process. In an example in which the base substrate is seated on the stage, on which the resin is applied, the base substrate may be maintained in a bent state corresponding to the shape of the stage. Accordingly, when the resin is seated on the stage and a curing process of the resin is performed, the shape of the resin may be stably maintained, and occurrence of thickness deviation in the resin layer may be prevented.

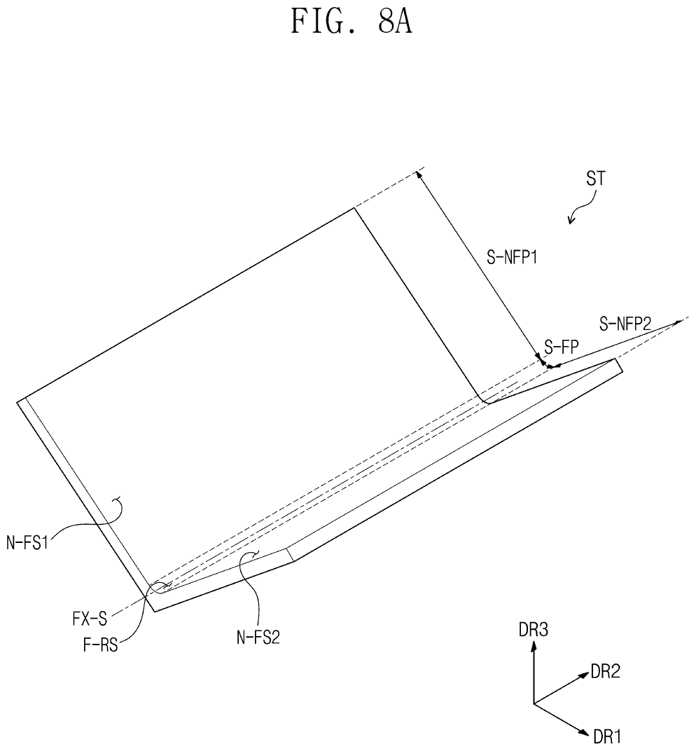

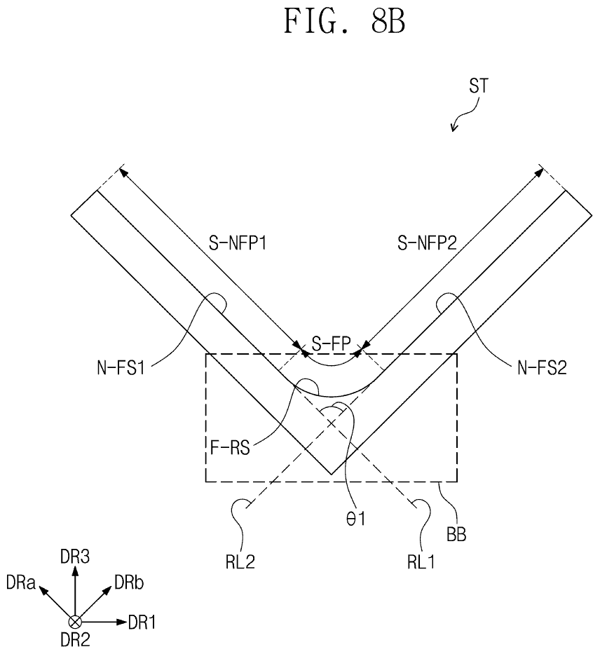

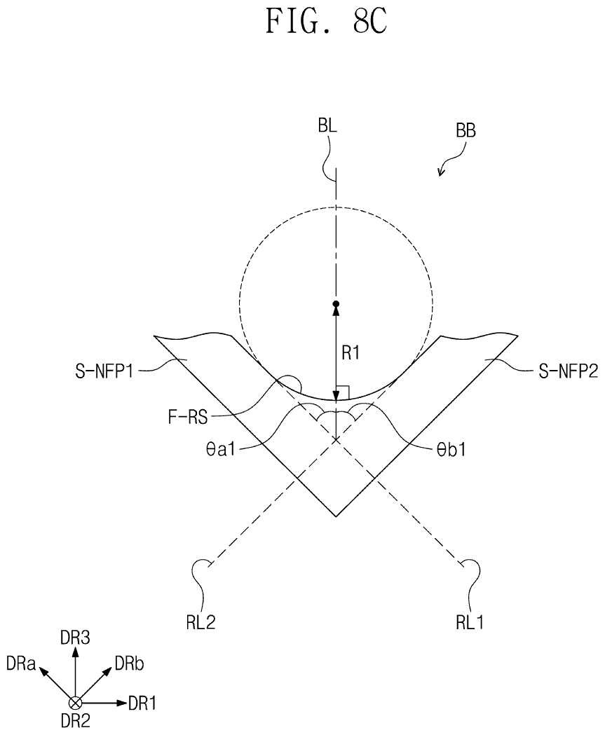

FIGS. 8A to 8C are drawings illustrating a configuration of a window manufacturing apparatus according to an embodiment of the present disclosure. FIG. 8A is a perspective view illustrating a stage ST that constitutes the window manufacturing apparatus of an embodiment. FIG. 8B is a cross-sectional view illustrating the stage ST that constitutes the window manufacturing apparatus of an embodiment. FIG. 8C is a cross-sectional view illustrating a part of the stage ST that constitutes the window manufacturing apparatus of an embodiment. FIG. 8C is a cross-sectional view illustrating a part corresponding to area BB of FIG. 8B.

Referring to FIGS. 8A to 8C, the window manufacturing apparatus of an embodiment may include the stage ST.

The stage ST may include a first part S-FP, a second part S-NFP1, and a third part S-NFP2. The second part S-NFP1 and the third part S-NFP2 may be spaced apart from each other along the first direction DR1 with the first part S-FP being interposed between the second part S-NFP1 and the third part S-NFP2. In the stage ST, the first part S-FP may be a part including a curved surface F-RS, the second part S-NFP1 may be a part including a first flat surface N-FS1, and the third part S-NFP2 may be a part including a second flat surface N-FS2. The curved surface F-RS of the first part S-FP, the first flat surface N-FS1 of the second part S-NFP1, and the second flat surface N-FS2 of the third part S-NFP2 may define an inner surface of the stage ST. In the specification, the first part may be referred to as a curved part, and the second part and the third part may be referred to as flat parts.

In the stage ST, the first part S-FP may be a part corresponding to a folding part W-FP (see FIG. 6A) of the base substrate W-BS (see FIG. 6A) of the window WM (see FIG. 6A), the second part S-NFP1 may be a part corresponding to a first non-folding part W-NFP1 of the base substrate W-BS (see FIG. 6A) of the window WM (see FIG. 6A), and the third part S-NFP2 may be a part corresponding to a second non-folding part W-NFP2 of a base substrate W-BS (see FIG. 6A) of the window WM (see FIG. 6A). In an embodiment, the first part S-FP, the second part S-NFP1, and the third part S-NFP2 may have an integral shape.

The first part S-FP may be disposed between the second part S-NFP1 and the third part S-NFP2. In the stage ST, the first part S-FP may be defined as a part between a portion, at which the second part S-NFP1 starts, and a portion, at which the third part S-NFP2 starts. The first part S-FP may connect the second part S-NFP1 and the third part S-NFP2. In the stage ST of an embodiment, the first part S-FP may be a part that is bent with respect to the folding axis FX-S of the stage, which extends in a direction that is parallel to the second direction DR2.

The first part S-FP may include a curved surface F-RS. On the cross-section defined by the first direction DR1 and the third direction DR3, the curved surface F-RS of the first part S-FP may be a part of a circle having a specific radius of curvature, or a part of an ellipse on the cross-section. As illustrated in FIG. 8C, the curved surface F—RS may have a concavely curved shape having a first radius R1 of curvature. The first radius R1 of curvature of the curved surface F—RS may be appropriately adjusted depending on a shape of the targeted resin layer RL (FIG. 6A). However, the embodiment is not limited thereto, and unlike the illustration of FIG. 8C, the curved surface F—RS may have a shape having a variable curvature, in which parts having different radii of curvature are connected to each other.

Referring to FIG. 8B, the second part S-NFP1 and the third part S-NFP2 may extend from opposite ends of the first part S-FP. The second part S-NFP1 may have a shape that extends along a first extension direction DRa. The third part S-NFP2 may have a shape that extends along a second extension direction DRb that is different from the first extension direction DRa. A third direction DR3 that is a thickness direction may be located between the first extension direction DRa and the second extension direction DRb.

An extension direction of the second part S-NFP1 and an extension direction of the third part S-NFP2 may not be parallel to each other. That is, a first extension direction DRa that is the extension direction of the second part S-NFP1, and a second extension direction DRb that is the extension direction of the third part S-NFP2 may not be parallel to each other. In the specification, an extension direction or an extension plane of the second part S-NFP1 may mean an extension direction or an extension plane of the first flat surface N-FS1, and an extension direction or an extension plane of the third part S-NFP2 may mean an extension direction or an extension plane of the second flat surface N-FS2.

A distance between the extension plane of the second part S-NFP1 and the extension plane of the third part S-NFP2 may increase as the second part S-NFP1 and the third part S-NFP2 become more distant from the first part S-FP. In detail, the first flat surface N-FS1 of the second part S-NFP1 and the second flat surface N-FS2 of the third part S-NFP2 may not be parallel to each other. A distance between the first flat surface N-FS1 and the second flat surface N-FS2 may increase as the first flat surface N-FS1 and the second flat surface N-FS2 become more distant from the first part S-FP. A spacing distance between the second part S-NFP1 and the third part S-NFP2 may be fixed with the first part S-FP being interposed between the second part S-NFP1 and the third part S-NFP2.

The second part S-NFP1 and the third part S-NFP2 may have a flat shape. The second part S-NFP1 and the third part S-NFP2 may not include a curved surface. The second part S-NFP1 may include a first flat surface N-FS1 that extends from one end of the curved surface F-RS of the first part S-FP, and the third part S-NFP2 may include a second flat surface N-FS2 that extends from an opposite end of the curved surface F-RS of the first part S-FP.

In FIGS. 8A to 8C, it is illustrated that extents of the second part S-NFP1 and the third part S-NFP2 that are spaced apart from each other are the same, but the embodiment is not limited thereto. The extents of the second part S-NFP1 and the third part S-NFP2 disposed with the first part S-FP being interposed between the second part S-NFP1 and the third part S-NFP2 may be different. The extents of the second part S-NFP1 and the third part S-NFP2 may be appropriately changed depending on the shape of the target substrate seated on the stage ST.

The first flat surface N-FS1 of the second part S-NFP1 may define a first angle θ1 with the second flat surface N-FS2 of the third part S-NFP2. The first angle θ1 may refer to an angle that is defined by a first extension line RL1 that is an extension line of the first flat surface N-FS1, and a second extension line RL2 that is an extension line of the second flat surface N-FS2. In an embodiment, the first angle θ1 may be not less than 60 degrees and not more than 179.5 degrees. Expressed another way, the first angle θ1 may range from 60 degrees to 179.5 degrees.

With respect to a reference line BL that is parallel to a normal line at the central point of the first part S-FP, the first flat surface N-FS1 may be inclined at a first sub-angle θa1 with respect to the reference line BL, and the second flat surface N-FS2 may be inclined at a second sub-angle θb1 with respect to the reference line BL. The first angle θ1 defined by the first flat surface N-FS1 and the second flat surface N-FS2 may be defined as a sum of a first sub-angle θa1 and a second sub-angle θb1.

The first sub-angle θa1 and the second sub-angle θb1 may be the same (e.g., equal) or different. In an example in which the first sub-angle θa1 and the second sub-angle θb1 are the same, the second part S-NFP1 and the third part S-NFP2 may be symmetrical with respect to the first part S-FP on a cross-section that is defined by the first direction DR1 and the third direction DR3. However, the embodiment is not limited thereto, and the first sub-angle θa1 and the second sub-angle θb1 may be different.

A width of the second part S-NFP1 in the first extension direction DRa may be the same as a width of the third part S-NFP2 in the second extension direction DRb. However, the embodiment is not limited thereto, and the width of the second part S-NFP1 in the first extension direction DRa and the width of the third part S-NFP2 in the second extension direction DRb may be different. For example, the width of the second part S-NFP1 in the first extension direction DRa may be greater than the width of the third part S-NFP2 in the second extension direction DRb.

A seating surface, on which a target substrate is seated, may be defined in the stage ST. The seating surface may be defined as an inner surface of the stage ST. That is, the seating surface may be defined by the curved surface F-RS of the first part S-FP, the first flat surface N-FS1 of the second part S-NFP1, and the second flat surface N-FS2 of the third part S-NFP2.

In the stage ST, the first flat surface N-FS1 and the second flat surface N-FS2 may contact the target substrate. The target substrate may be the base substrate W-BS (FIG. 6A) before the resin layer RL (FIG. 6A) is formed in the window WM (FIG. 6A). In the stage ST, the curved surface F-RS may not contact the target substrate. The curved surface F-RS may be a non-contact surface that does not contact the target substrate. In an example in which the target substrate is seated on the stage ST, the target substrate may contact the second part S-NFP1 and the third part S-NFP2, and may not contact the first part S-FP. In a state, in which the target substrate is seated on the stage ST, a space that is filled with the resin may be formed between the target substrate and the first part S-FP.

When the base substrate W-BS (FIG. 6A) that is the target substrate is seated on the stage ST, the base substrate W-BS may be disposed such that one surface of the base substrate W-BS (FIG. 6A), on which the recessed part HP is defined, faces the seating surface of the stage ST. For example, the base substrate W-BS may be disposed on the stage ST such that the first base surface BS-F1, on which the recessed part HP is defined, faces the seating surface of the stage ST. In a state, in which the base substrate W-BS (FIG. 6A) is seated on the stage ST, a part of the first base surface BS-F1, which corresponds to the first non-folding part W-NFP1, may contact the first flat surface N-FS1, and a part of the first base surface BS-F1, which corresponds to a second non-folding part W-NFP2, may contact the second flat surface N-FS2. In a state, in which the base substrate W-BS (FIG. 6A) is seated on the stage ST, a space, in which the resin may be filled, may be formed between the base substrate W-BS (FIG. 6A) and the first part S-FP.

A material of the stage ST is not particularly limited, but may include a material having a high stiffness. Accordingly, when the target substrate is seated, deformation of the shape of the stage ST may be suppressed, and a processing performance of the resin layer RL that will be described herein may be improved. For example, the stage ST may include glass, plastic, or metal.

In an embodiment, the stage ST may further include a hydrophobic material. Because the stage ST includes a hydrophobic material, an affinity between the resin provided to the stage ST and the stage ST becomes lower such that the resin that has undergone the curing process may be easily separated from the stage ST. A type of the hydrophobic material is not particularly limited, but may include a hydrophobic polymer, such as, for example, a release agent, a fluorine-based resin, parylene, and Teflon.

The release agent (or a release material) is not particularly limited. For example, the release agent (or a release material) may be a material that may be commonly used in the art. In some examples, the release agent (or a release material) may be an alkyd release agent, a silicone release agent, a fluorine release agent, an unsaturated ester release agent, a polyolefin release agent, or a wax release agent. However, embodiments of the present disclosure are not limited thereto.

In an embodiment, the stage ST may be formed by adding the hydrophobic material to a base material including a polymer. Alternatively, the stage ST may be formed by surface-treating a substrate composed of a polymer with the hydrophobic material. However, the embodiment is not limited thereto, and when the hydrophobic polymer has a sufficient stiffness, the stage ST may include the hydrophobic polymer, without including an additional polymer.

In an embodiment, the stage ST may include glass or metal, and at least a portion of the surface of the stage ST may be treated with the hydrophobic material. For example, the stage ST may include glass or metal, and at least a curved surface F-RS of the stage ST may be treated with a hydrophobic material. However, the embodiment is not limited thereto, and the entire seating surface of the stage ST, on which the target substrate is seated, may be treated with the hydrophobic material. For example, the curved surface F-RS, the first flat surface N-FS1, and the second flat surface N-FS2 of the stage ST may all be treated with the hydrophobic material. Because the curved surface F-RS that contacts at least the resin is hydrophobic-treated, the affinity with the resin becomes lower such that the resin that contacts the curved surface F—RS may be easily separated after the curing process.

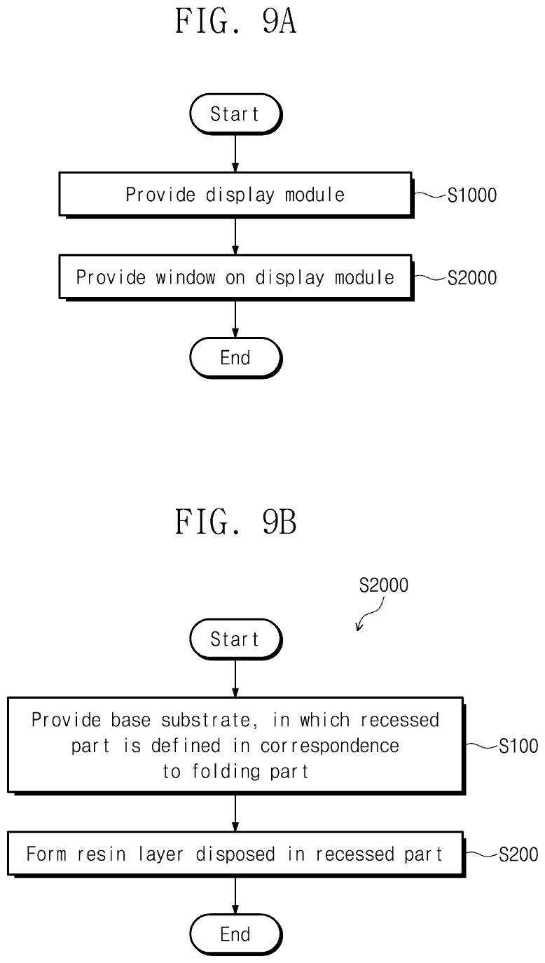

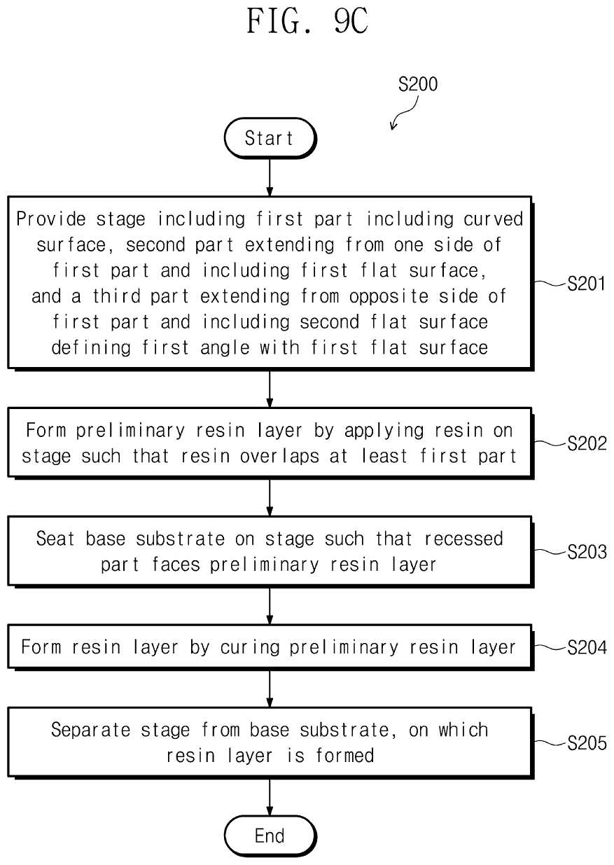

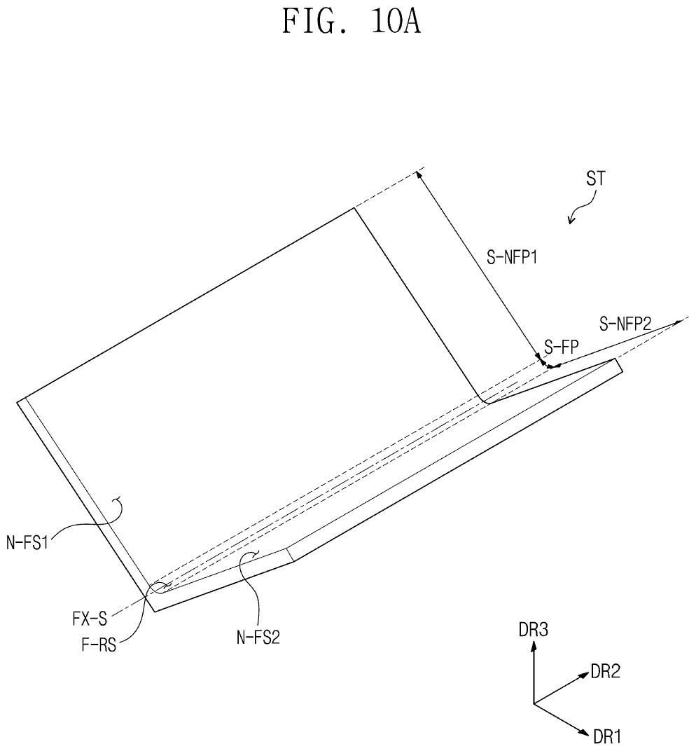

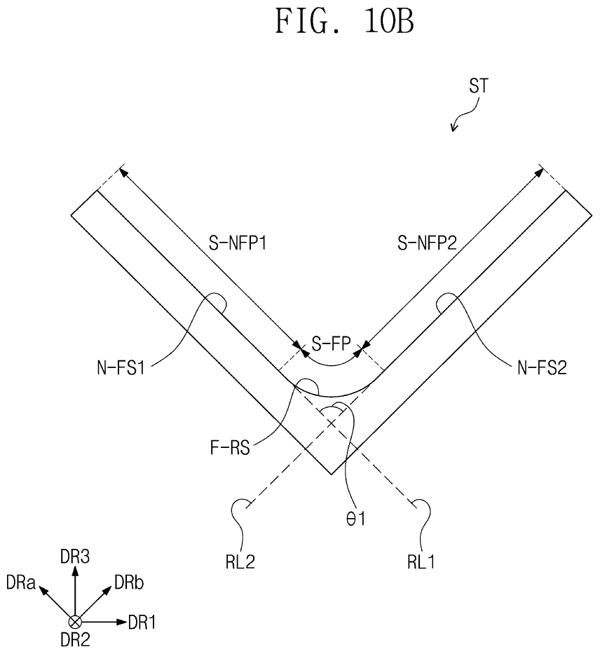

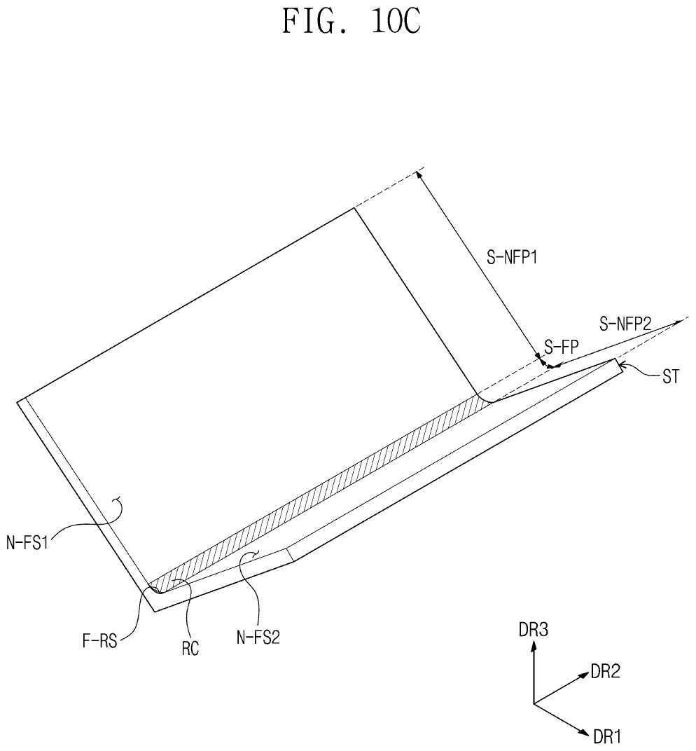

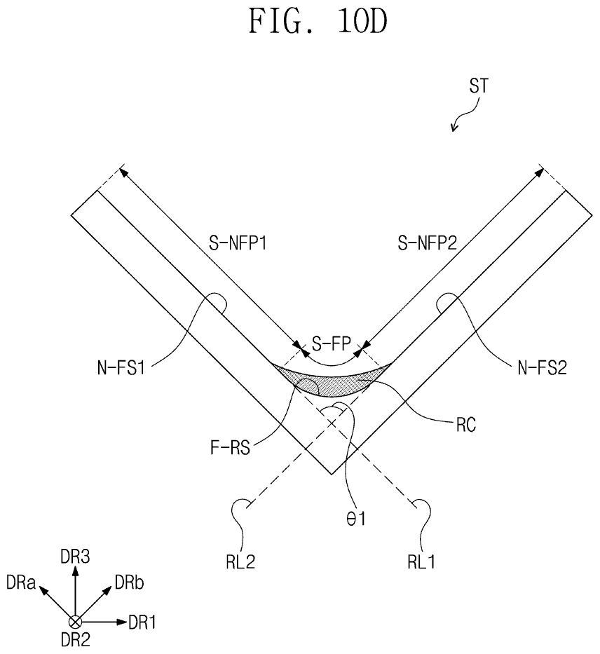

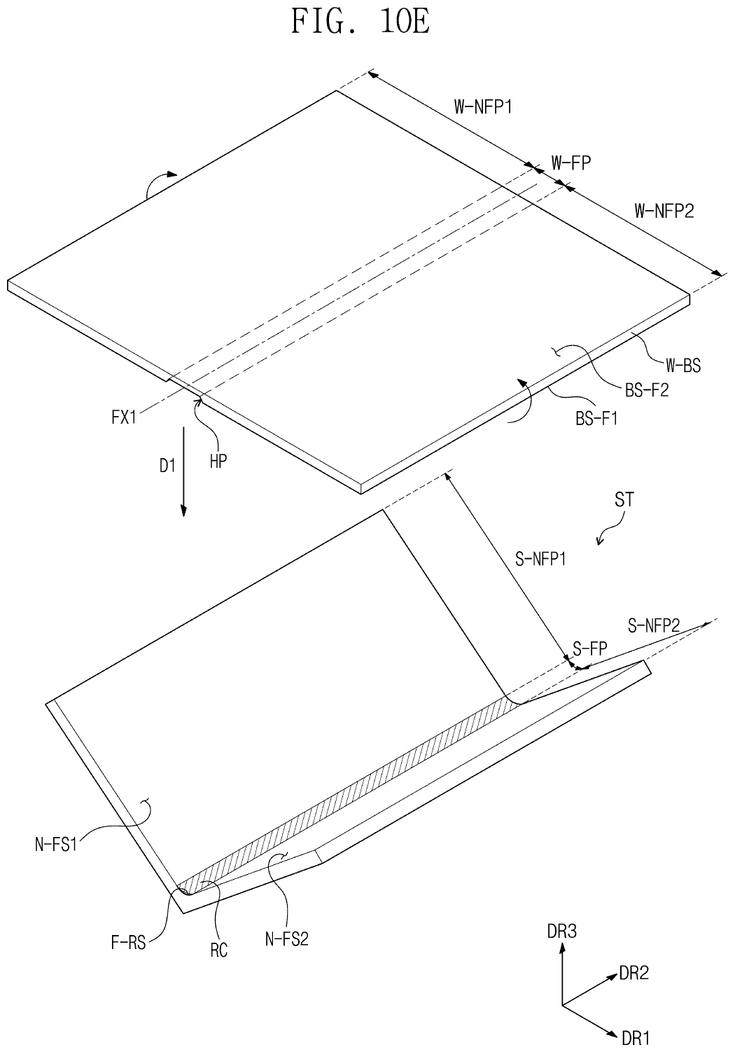

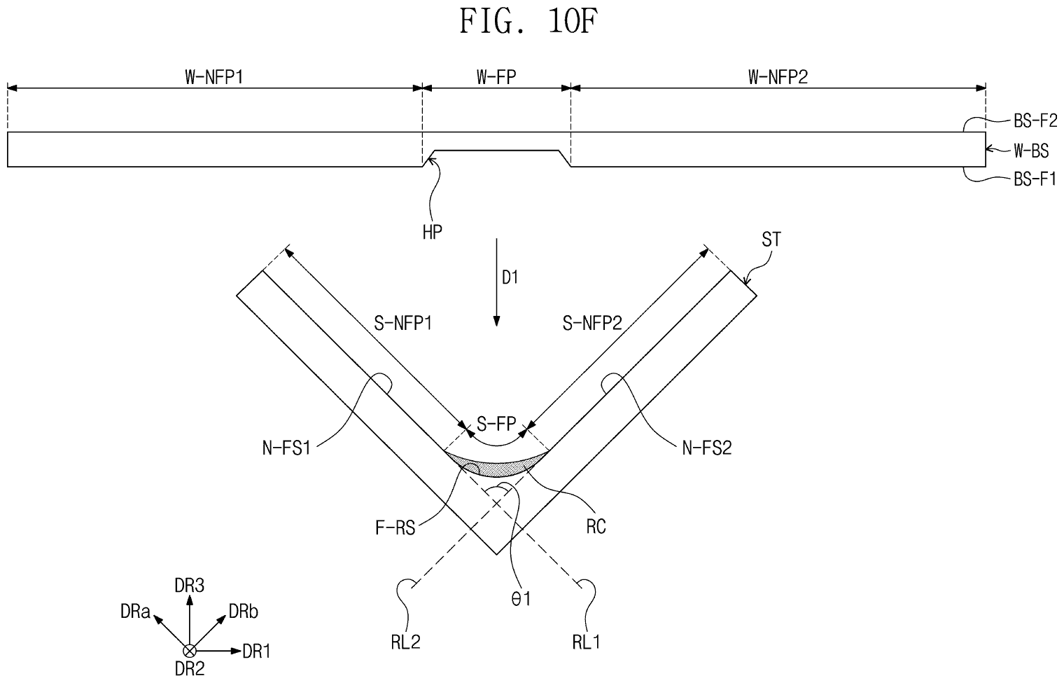

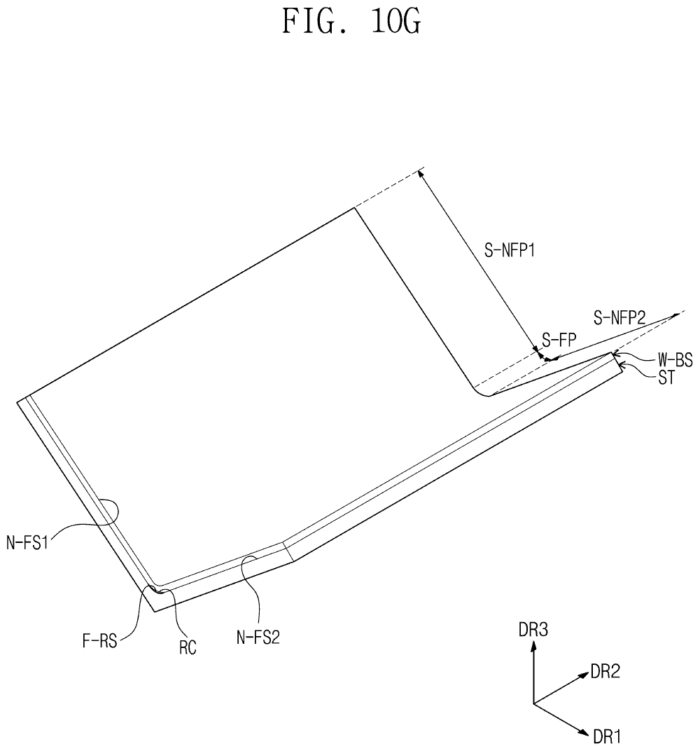

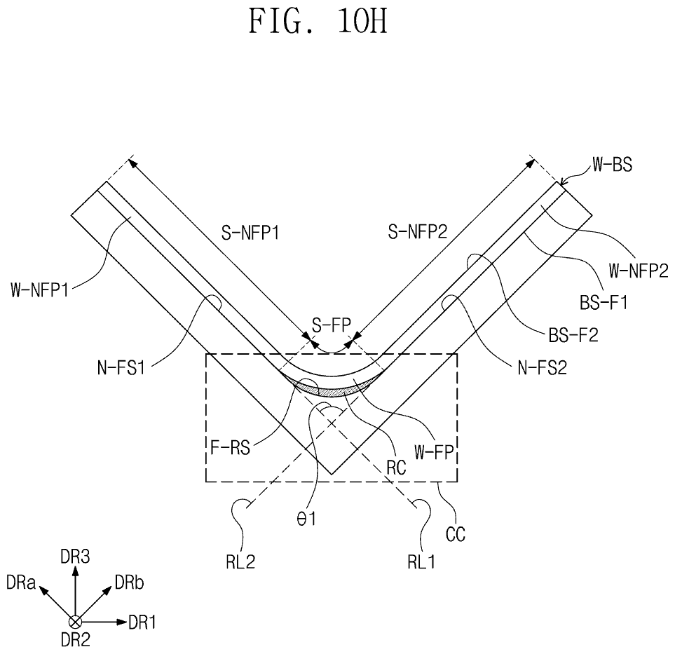

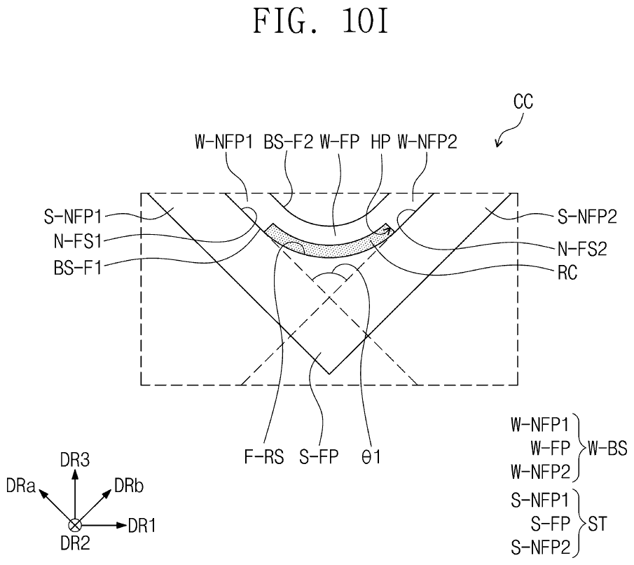

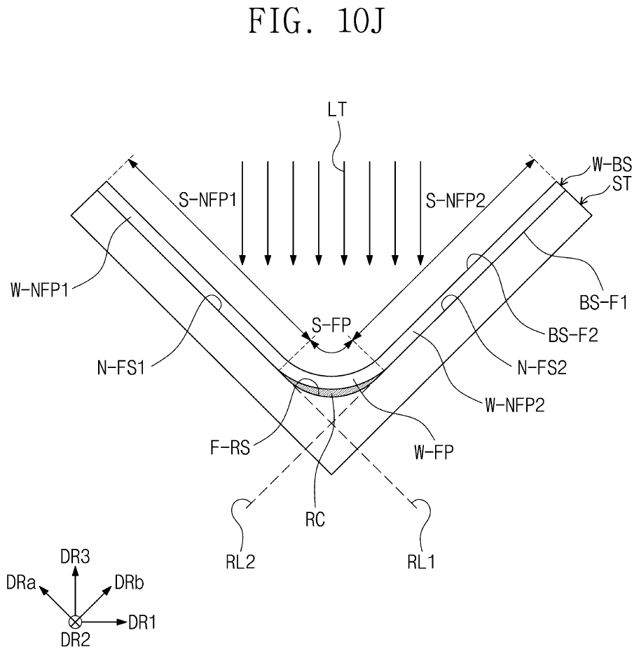

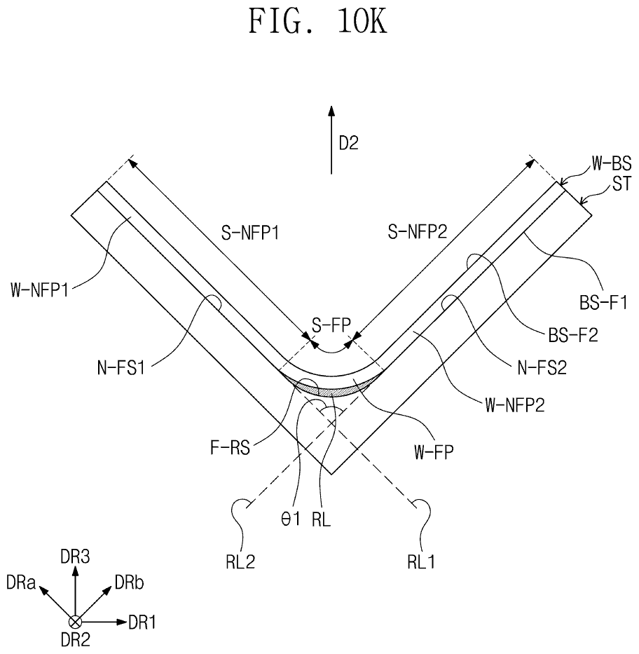

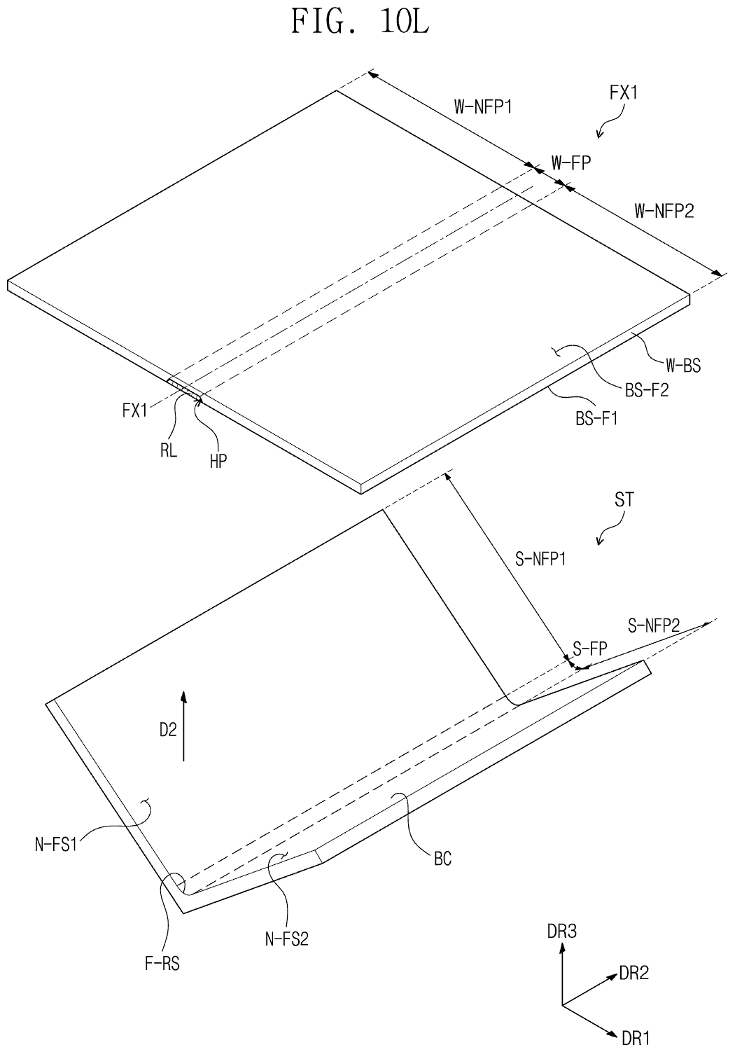

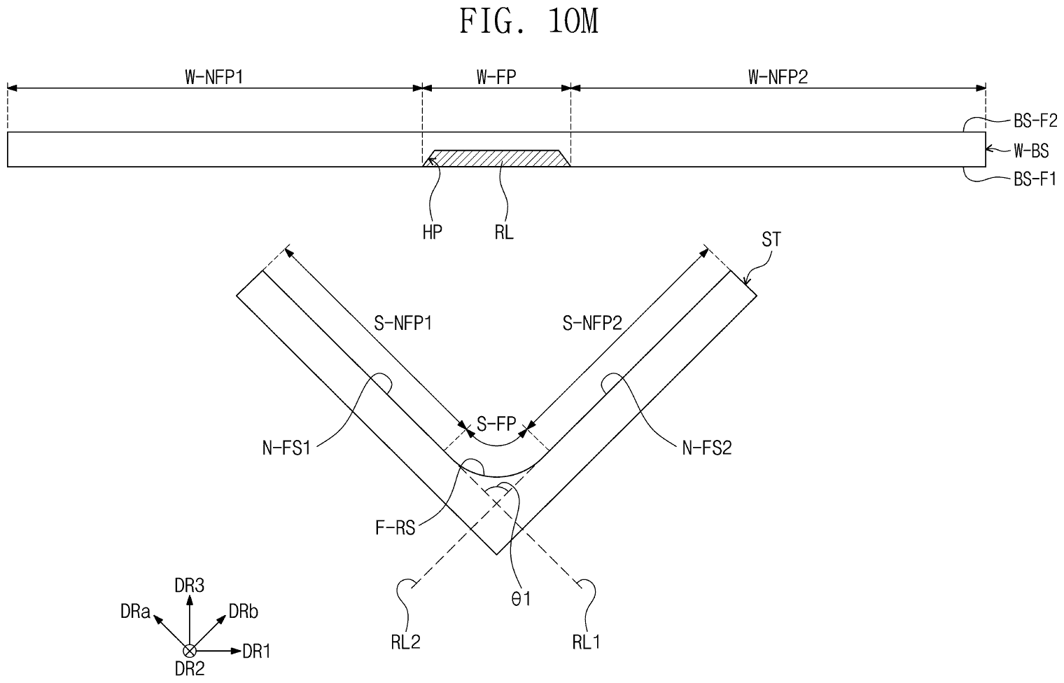

Hereinafter, a method for manufacturing a window of an embodiment will be described with reference to FIGS. 9A to 9C and FIGS. 10A to 10M. In a description of the method for manufacturing a display device of an embodiment, the description of the display device of the above-described embodiment may be applied to the display device. In the description of the method for manufacturing a display device of an embodiment below, any repeated contents of the description of the display device of the above-described embodiment will not be described again, and differences will be mainly described.

The method for manufacturing a display device of an embodiment may be a method for manufacturing the display device ED of an embodiment described in FIGS. 1A to 4. An embodiment provides a method of manufacturing a display device including the window WM that is disposed on the display module DM of the display device ED.

FIG. 9A is a flowchart illustrating a method for manufacturing a display device according to an embodiment of the present disclosure. FIG. 9B is a flowchart illustrating a method for manufacturing a window according to an embodiment of the present disclosure. FIG. 9C is a flowchart detailing an operation of forming a resin layer in a method for manufacturing a window according to an embodiment of the present disclosure.

Referring to FIG. 9A, the method for manufacturing a display device according to an embodiment includes an operation S1000 of providing a display module, and an operation S2000 of providing a window on the display module.

Referring to FIG. 9B, the method for manufacturing a window according to an embodiment includes an operation S100 of providing a base substrate, in which a recessed part is defined in correspondence to a folding part, and an operation S200 of forming a resin layer disposed in the recessed part.

Referring to FIG. 9C, the operation S200 of forming a resin layer includes an operation S201 of providing a stage including a first part including a curved surface, a second part that extends from a side of the first part and including a first flat surface, and a third part that extends from an opposite side of the first part and including a second flat surface that defines a first angle with the first flat surface, an operation S202 of forming a preliminary resin layer by applying a resin on the stage such that the resin overlaps at least the first part, an operation S203 of seating a base substrate on the stage such that the recessed part faces the preliminary resin layer, an operation S204 of forming a resin layer by curing the preliminary resin layer, and an operation S205 of separating the stage from the base substrate on which the resin layer is formed. In the display device ED of the embodiment described herein in FIGS. 1A to 7B, and the like, the resin layer RL included in the window WM may be formed through an operation for forming a resin layer that will be described herein.

FIGS. 10A to 10M are views illustrating some operations of a method for manufacturing a display device according to an embodiment of the present disclosure. FIGS. 10A to 10M illustrate an operation of manufacturing the window WM that is disposed on the display module DM of the display device ED by using the window manufacturing apparatus according to an embodiment of the present disclosure. FIG. 10I is a cross-sectional view illustrating a part corresponding to area CC of FIG. 10H. FIGS. 10A and 10B illustrate an operation of providing a stage ST, FIGS. 10C and 10D illustrate an operation of forming a preliminary resin layer RC by applying a resin on the stage ST, FIGS. 10E to 10I illustrate an operation of seating a base substrate W-BS on the stage such that a recessed part HP faces the preliminary resin layer RC, FIG. 10J illustrate an operation of forming a resin layer RL by curing the preliminary resin layer RC, and FIGS. 10K to 10M illustrate an operation of separating the stage ST from the base substrate W-BS, on which the resin layer RL is formed.

Referring to FIGS. 10A and 10B, the method for manufacturing a window according to an embodiment of the present disclosure may include an operation of providing the stage ST. The stage ST included in the method for manufacturing method according to an embodiment may be the same as the stage ST included in the window manufacturing apparatus described herein in FIGS. 8A to 8C. The stage ST may include a first part S-FP including a curved surface F-RS, and a second part S-NFP1 and a third part S-NFP2 that extend from opposite ends of the first part S-FP and are spaced apart from each other in the first direction DR1. The second part S-NFP1 may include a first flat surface N-FS1 that extends from one end of the curved surface F-RS, and the third part S-NFP2 may include a second flat surface N-FS2 that extends from an opposite end of the curved surface F-RS. The curved surface F-RS, the first flat surface N-FS1, and the second flat surface N-FS2 may define a seating surface, on which a target substrate is seated.

Referring to FIGS. 10C and 10D, the method for manufacturing a window according to an embodiment may include an operation of forming the preliminary resin layer RC by applying the resin such that the resin overlaps at least the first part S-FP on the stage ST. The preliminary resin layer RC may be formed by applying the resin on the stage ST. The resin may be provided in a liquid state, and the preliminary resin layer RC may be a liquid coating layer before being cured.

The resin may be provided on the first part S-FP of the stage ST. The resin may be provided such that the resin covers at least a portion of a curved surface F-RS of the first part S-FP. In an embodiment, the resin may be provided to entirely cover the curved surface F-RS. As illustrated in FIG. 10D, in a state, in which the first part S-FP of the stage ST is disposed on a lowermost part with respect to the third direction DR3, the provided resin may be collected on the first part S-FP due to gravity.

The resin may include an optical clear resin or an optical clear adhesive. However, the optical clear resin and the optical clear adhesive are not particularly limited. For example, the optical clear resin and the optical clear adhesive may be commonly used materials. In some examples, the optical clear resin and the optical clear adhesive may be a polyurethane-based material, a polyacrylic-based material, a polyester-based material, a polyepoxy-based material, or a polyvinyl acetate-based material, and a mixture of one or two or more thereof may be used, but embodiments of the present disclosure are not limited thereto.

The resin may be provided in various ways. For example, the resin may be provided by spin-coating, a slot-die, ink-jet printing, spray coating, and the like.

The resin may include an uncured oligomer or monomer. The uncured oligomer or monomer may include a cross-linking group. Furthermore, the resin may include an initiator. The type of the initiator is not particularly limited. For example, the initiator may be of any suitable type which promotes the curing reaction. In an example, the initiator may be a photoinitiator.

The resin may include at least one photoinitiator. In an embodiment, the photoinitiator may be a photoinitiator that is activated by light in the ultraviolet range. The photoinitiator may be a photoinitiator activated by ultraviolet light having a center wavelength in the wavelength range of 100 nm to 400 nm. In an example in which the resin includes a plurality of photoinitiators, different photoinitiators may be activated by ultraviolet light in different center wavelength ranges. In the specification, the center wavelength indicates the wavelength that exhibits a maximum intensity of an emission peak in an emission spectrum of a light source.

The photoinitiator may be any one selected from 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-1.

Furthermore, the photoinitiator may be any one selected from 2-methyl-1-[4-(methylthio)phenyl]-2-morpholinopropan-1-1,2-benzyl-2-dimethylamino-1-(4-morpholinophenyl-butanone-1,2-dimethylamino-2-(4-methyl-benzyl-1-(4-morpholin-4-yl-phenyl-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphineoxide, [1-(4-phenylsulfanylbenzoylheptylideneamino]benzoate, [1-[9-ethyl-6-(2-methylbenzoylcarbazol-3-yl]ethylideneamino]acetate, and bis(2,4-cyclopentadienylbis[2,6-difluoro-3-(1-pyrrylphenyl] titanium (IV). However, embodiments of the present disclosure are not limited thereto.

The resin may further include an additive as applicable or desired in accordance with one or more embodiments of the present disclosure. The additive may be appropriately selected from general additives known in the art to control the properties desired or targeted for the adhesive composition. For example, the additive may include a light stabilizer, a crosslinking agent, an antioxidant, a chain transfer agent, a photosensitizer, a polymerization inhibitor, a leveling agent, a surfactant, an adhesion-imparting agent, a plasticizer, an ultraviolet absorber, a storage stabilizer, an antistatic agent, an inorganic filler, a pigment, and a dye, but is not limited to. The additive may be used alone or in combination of two or more.

Referring to FIGS. 10C and 10D, on a plane defined by the first direction DR1 and the second direction DR2, the preliminary resin layer RC formed from the resin may overlap the first part S-FP of the stage ST. The preliminary resin layer RC may contact the curved surface F-RS of the first part S-FP. The preliminary resin layer RC may cover at least a portion of the curved surface F-RS. The preliminary resin layer RC may cover the entire curved surface F-RS.

As illustrated in FIG. 10D, on a plane that is parallel to the first extension direction DRa, a portion of the preliminary resin layer RC may overlap the second part S-NFP1. Furthermore, on a plane that is parallel to the second extension direction DRb, a portion of the preliminary resin layer RC may overlap the third part S-NFP2. However, the embodiment is not limited thereto, and the range, in which the preliminary resin layer RC is applied in the stage ST, may be appropriately changed depending on the type of resin, and the thickness and the shape of the intended resin layer RC. For example, unlike the illustration of FIG. 10D, the preliminary resin layer RC may overlap the first part S-FP, and may not overlap the second part S-NFP1 and the third part S-NFP2.

Referring to FIGS. 10E to 10I, the method for manufacturing a window according to an embodiment of the present disclosure may include an operation of seating a target substrate on the stage ST. The target substrate may be the base substrate W-BS before the resin layer RL (FIG. 6A) is formed in the window WM (FIG. 6A).

In an embodiment of the method for manufacturing a window, the base substrate W-BS may be seated on the stage ST such that the preliminary resin layer RC is disposed in the recessed part HP. As illustrated in FIGS. 10E and 10F, the base substrate W-BS that is a target substrate may be moved in a first movement direction D1 to seat the base substrate W-BS on the stage ST. After the base substrate W-BS, in which the recessed part HP is defined, is prepared, the base substrate W-BS may be moved in the first movement direction D1 in a state, in which one surface of the base substrate W-BS, in which the recessed part HP is defined, faces the preliminary resin layer RC such that the base substrate W-BS may be seated on the stage ST. The first movement direction may be an opposite direction to the third direction DR3 that is a thickness direction.

In the method for manufacturing a window of an embodiment, a state, in which the first non-folding part W-NFP1, the folding part W-FP, and the second non-folding part W-NFP2 are flat, is defined as a first state of the base substrate W-BS, and a state, in which the folding part W-FP is folded such that the base substrate W-BS corresponds to a shape of a stage ST, is defined as a second state. The base substrate W-BS may be changed from the first state to the second state in the operation of seating the base substrate W-BS on the stage ST.

A state, in which the first non-folding part W-NFP1, the folding part W-FP, and the second non-folding part W-NFP2 of the base substrate W-BS are flat, may be defined as the first state. In an example in which the base substrate W-BS is in the first state, the first non-folding part W-NFP1, the folding part W-FP, and the second non-folding part W-NFP2 may be disposed on the same plane and be flat. The first state may mean a state, in which the folding part W-FP of the base substrate W-BS is unfolded. That is, the first state may mean an unfolded state, in which no external force is applied to the base substrate W-BS. Referring to FIGS. 10E and 10F, before the base substrate W-BS is seated on the stage ST, the base substrate W-BS may be in the first state.

A state, in which the folding part W-FP is folded such that the base substrate W-BS corresponds to the shape of the stage ST, may be defined as the second state. In the second state, the folding part W-FP of the base substrate W-BS may have a shape that is folded at a specific angle. Referring to FIG. 10G and FIG. 10H, after the base substrate W-BS is seated on the stage ST, the base substrate W-BS may be in the second state.

In the second state, an extension plane of the first non-folding part W-NFP1 and an extension plane of the second non-folding part W-NFP2 may define a second angle. In the specification, the extension plane of the first non-folding part W-NFP1 may mean an extension plane of one surface of the first non-folding part W-NFP1, which is adjacent to the stage ST, and the extension plane of the second non-folding part W-NFP2 may mean an extension plane of one surface of the first non-folding part W-NFP1, which is adjacent to the stage ST. In an embodiment, a second angle defined by the extension plane of the first non-folding part W-NFP1 and the extension plane of the second non-folding part W-NFP2 may be substantially equal to the first angle described herein. For example, the second angle may range from 60 degrees to 179.5 degrees.

Referring to FIGS. 10H and 10I, in a state, in which the base substrate W-BS is seated on the stage ST, at least a portion of one surface of the base substrate W-BS, on which the recessed part HP is defined, may contact the stage. As illustrated in FIG. 10I, at least a portion of the first base surface BS-F1 of the base substrate W-BS, on which the recessed part HP is defined, may contact the stage ST. Among the first base surface BS-F1 of the base substrate W-BS, a first portion of the first base surface BS-F1 corresponding to the first non-folding part W-NFP1 may contact the second part S-NFP1 of the stage ST. Furthermore, among the first base surface BS-F1 of the base substrate W-BS, a second portion of the first base surface BS-F1 corresponding to the second non-folding part W-NFP2 may contact the third part S-NFP2 of the stage ST.

In a state, in which the base substrate W-BS is seated on the stage ST, a portion of the first base surface BS-F1 of the base substrate W-BS, at which the recessed part HP is defined, may not contact the stage ST. A portion of the first base surface BS-F1 of the base substrate W-BS, at which the recessed part HP is defined, may not contact the curved surface F-RS of the stage ST, and may be spaced apart therefrom by a specific distance. In the operation of seating the base substrate W-BS on the stage ST, the recessed part HP may contact the preliminary resin layer RC. The preliminary resin layer RC may be disposed between the recessed part HP and the curved surface F-RS.

In a state, in which the base substrate W-BS is seated on the stage ST, a filling space may be formed between the recessed part HP of the base substrate W-BS and the first part S-FP of the stage ST. The filling space may be defined by one surface of the base substrate W-BS, on which the recessed part HP is defined, and the curved surface F-RS of the first part S-FP. The preliminary resin layer RC may be disposed in the filling space. In a state, in which the base substrate W-BS is seated on the stage ST, the preliminary resin layer RC may contact one surface of the base substrate W-BS, on which the recessed part HP is defined, and the curved surface F-RS of the first part S-FP.

The method for manufacturing a window according to an embodiment of the present disclosure may further include an operation of pressing the folding part W-FP of the base substrate W-BS after the operation of seating the base substrate W-BS on the stage ST. After the base substrate W-BS is seated on the stage ST, the folding part W-FP of the base substrate W-BS may be pressed in a direction that faces the stage ST. In the operation of pressing the folding part W-FP, the preliminary resin layer RC may entirely fill in the recessed part HP. However, the embodiment is not limited thereto, and the operation of pressing the folding part W-FP of the base substrate W-BS may be omitted depending on the process.

In FIGS. 10A to 10M, the extents of the first non-folding part W-NFP1 of the base substrate W-BS and the second part S-NFP1 of the stage ST are the same, and the extents of the second non-folding part W-NFP2 of the base substrate W-BS and the third part S-NFP2 of the stage ST are the same, but the embodiment is not limited thereto. For example, the extent of the second part S-NFP1 of the stage ST may be greater than the extent of the first non-folding part W-NFP1, and the extent of the third part S-NFP2 of the stage ST may be greater than the extent of the second non-folding part W-NFP2.

Referring to FIG. 10J, the method for manufacturing a window according to an embodiment of the present disclosure may include an operation of forming the resin layer RL by curing the preliminary resin layer RC.

After the base substrate W-BS is seated on the stage ST, the operation of curing the preliminary resin layer RC may be performed while the base substrate W-BS is seated on the stage ST. In the method for manufacturing a window according to an embodiment of the present disclosure, light or heat may be applied to the preliminary resin layer RC to form the preliminary resin layer RC. Hereinafter, applying light LT to the preliminary resin layer RC will be described as an example. In the operation of curing the preliminary resin layer RC, light LT may be applied to the entire preliminary resin layer RC.

In the method for manufacturing a window according to an embodiment, the operation of curing the preliminary resin layer RC may be performed while the base substrate W-BS is seated on the stage ST. The operation of curing the preliminary resin layer RC may be performed while the base substrate W-BS is seated on the stage ST. That is, the operation may be performed in the second state of the base substrate W-BS. The base substrate W-BS may be cured by irradiating light, for example, ultraviolet light, to the preliminary resin layer RC while the base substrate W-BS is seated on the stage ST in the second state. In the operation of curing the preliminary resin layer RC, the preliminary resin layer RC may be fixed in a state, in which the recessed part HP is disposed.

Light may be applied to the preliminary resin layer RC from a light source disposed on the base substrate W-BS through the base substrate W-BS. The base substrate W-BS may be formed of a material having a high light transmittance. The base substrate W-BS may be transparent. The base substrate W-BS may have a high ultraviolet transmittance.

In the method for manufacturing a window according to an embodiment, the operation of curing the preliminary resin layer RC in association with forming the resin layer RL may be an operation of fixing the shape of the preliminary resin layer RC filled in the recessed part HP. The preliminary resin layer RC that is a liquid coating layer may be changed into a solid resin layer RL (see FIG. 10M) by the light provided to pass through the base substrate W-BS.

In the operation of curing the preliminary resin layer RC, the preliminary resin layer RC may be cured while being disposed in the filling space. Because the preliminary resin layer RC is cured while being disposed in the filling space, exposure of the resin to oxygen may be limited during curing, and thus a curing efficiency may be improved, and thus a process efficiency may be increased. The preliminary resin layer RC may be disposed in the filling space, and may be surrounded by one surface of the base substrate W-BS, which defines the recessed part HP, and the curved surface F-RS of the first part S-FP. Accordingly, the exposure of the resin to oxygen during curing may be reduced, and the curing efficiency may be improved, and a separate process for blocking oxygen may be omitted during the curing process such that the process efficiency may be increased.

In the method for manufacturing a window of an embodiment, when an operation of pressing the folding part W-FP of the base substrate W-BS is further included, the operation of pressing the base substrate W-BS and the operation of curing the preliminary resin layer RC may be performed simultaneously. As the preliminary resin layer RC is cured while the base substrate W-BS is pressed, a filling rate of the preliminary resin layer RC in the recessed part HP may be improved, and a density of the preliminary resin layer RC filled in the recessed part HP may be uniform.

In the method for manufacturing a window of an embodiment, the area of the seating surface of the stage ST, in which the resin is applied, may be surface-treated with a hydrophobic material. The curved surface F-RS of the first part S-FP, on which the resin is applied in the stage ST, may be surface-treated with a hydrophobic material. As the curved surface F-RS that contacts the resin is hydrophobic-treated, an affinity with the resin becomes lower such that the cured resin layer RL may be easily separated from the stage ST in a subsequent operation of separating the stage ST. However, the embodiment is not limited thereto, and the second part S-NFP1 and the third part S-NFP2 of the stage ST may also be provided by being surface-treated with a hydrophobic material. In an example in which the first flat surface N-FS1 of the second part S-NFP1 and the second flat surface N-FS2 of the third part S-NFP2 are surface-treated with a hydrophobic material, an affinity of the first flat surface N-FS1 and the second flat surface N-FS2 with the resin may become lower. Accordingly, in the operation of seating the base substrate W-BS on the stage ST or the operation of pressurizing the base substrate W-BS, a phenomenon of the resin provided to the first part S-FP being leaked between the second part S-NFP1 and the first non-folding part W-NFP1 and between the third part S-NFP2 and the second non-folding part W-NFP2 may be prevented.

Referring to FIGS. 10K to 10M, the method for manufacturing a window according to an embodiment may include an operation of separating the stage ST from the base substrate W-BS, on which the resin layer RL is formed. After the preliminary resin layer RC (FIG. 10J) is cured and the resin layer RL is thereby formed, the base substrate W-BS, on which the resin layer RL is formed, may be moved in a second movement direction D2 to separate the base substrate W-BS and the stage ST. The second movement direction D2 may be parallel to the third direction DR3 that is the thickness direction.

In the method for manufacturing a window of an embodiment, when a state, in which the first non-folding part W-NFP1, the folding part W-FP, and the second non-folding part W-NFP2 are flat, is defined as a first state of the base substrate W-BS, and a state, in which the folding part W-FP is folded such that the base substrate W-BS corresponds to a shape of a stage ST, is defined as a second state, the base substrate W-BS may be changed from the second state to the first state in the operation of separating the stage ST. In a series of operations, in which the base substrate W-BS is seated on the stage ST to form a resin layer RL, the base substrate W-BS may be maintained in the second state. In an operation for separating the base substrate W-BS and the stage ST after the resin layer RL is formed, the base substrate W-BS may be changed from the second state to the first state.

The resin layer RL fixed through the curing process (e.g., the curing of the preliminary resin layer RC) may be separated from the stage ST together with the base substrate W-BS in the operation of separating the stage ST. Referring to FIGS. 10L and 10M, the resin layer RL may be fixed in a state of being disposed in the recessed part HP, and may be separated from the stage ST together with the base substrate W-BS in the operation of separating the stage ST.

Thereafter, the window WM manufactured by the operation of FIGS. 10A to 10M may be applied to the display device ED described herein. For example, the window WM manufactured by the operation of FIGS. 10A to 10M may be attached to the display module DM (FIGS. 7A and 7B). In the method for manufacturing a display device according to an embodiment, when the window WM is provided on the display module, the manufactured display device ED (FIG. 7A) may have the structure of FIG. 7A when the first base surface BS-F1, on which a recessed part HP is defined, is disposed closer to the display module DM (FIG. 7A) than the second base surface BS-F2. Furthermore, in the method for manufacturing a display device according to an embodiment, when the window WM is provided on a display module, the manufactured display device ED (FIG. 7B) may have the structure of FIG. 7B when the second base surface BS-F2 of the base substrate W-BS is disposed closer to the display module DM (FIG. 7B) than the first base surface BS-F1, on which the recessed part HP is defined.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

According to the method for manufacturing a window of the present disclosure, the resin layer is formed on the recessed part of the base substrate by using the curved stage, and a folding reliability may be secured and a thickness uniformity of the resin layer may be improved. The base substrate, in which the recessed part is defined to correspond to the folding part, may be disposed in a bent state on a stage, to which resin is applied. Thereafter, the resin may be cured while the base substrate is disposed on the stage to form the resin layer. As the resin layer is formed while the base substrate is bent at a specific angle, the tensile stress provided to the resin layer during the folding operation may be alleviated. Accordingly, the folding characteristics of the window may be improved, and damage due to the repeated folding operations of the display device may be prevented.

The window of an embodiment includes the base substrate, in which the recessed part is defined to correspond to the folding area, and the resin layer disposed in the recessed part whereby a mechanical strength of the folding part may be improved, and the folding characteristics may be improved at the same time. In the conventional method for manufacturing a window, a method of directly applying the resin into the recessed part and then curing the resin is applied as the process of forming the resin layer disposed in the recessed part. However, in this process, when the resin has a curing shrinkage, the uniformity of the thickness may be decreased due to the depth deviation of the recessed part. According to the present disclosure, because the stage has a curved shape, the occurrence of a deviation of a thickness of the resin layer may be prevented. By adjusting a curvature of the curved surface of the stage and the angle formed by the flat parts on opposite sides in consideration of the shrinkage rate of the resin, the extent and the shape of the resin filling space between the target substrate and the stage may be adjusted, and the phenomenon of unfilling due to the resin shrinkage may be prevented. Accordingly, a window having excellent folding characteristics and an improved reliability may be provided.

According to an embodiment of the present disclosure, in a process of forming the resin layer in the recessed part of the window including the base substrate, in which the recessed part is defined in correspondence to the folding part, the window having an improved folding reliability may be provided by forming the resin layer in the state, in which the base substrate is bent at a specific angle.

Although the present disclosure has been described with reference to the embodiments, it will be appreciated by an ordinary skilled in the art, to which the present disclosure pertains, that the present disclosure may be modified and changed within the scope of the appended claims without departing from the spirits and technical field of the present disclosure. Therefore, the technical scope of the present disclosure should not be limited to the detailed description of the specification, but should be determined by the claims.

What is claimed is:

1. A method for manufacturing a window, the method comprising:
providing a base substrate comprising a folding part, a first non-folding part, and a second non-folding part, wherein the first non-folding part and the second non-folding part face each other, with the folding part interposed between the first non-folding part and the second non-folding part, and a recessed part is defined in the base substrate in correspondence to the folding part; and
forming a resin layer disposed in at least the recessed part,
wherein the forming of the resin layer comprises:
providing a stage comprising a first part comprising a curved surface, a second part extending from a side of the first part and comprising a first flat surface, and a third part extending from an opposite side of the first part and comprising a second flat surface defining a first angle with the first flat surface;
forming a preliminary resin layer by applying a resin on the stage such that the resin overlaps at least the first part;
seating the base substrate on the stage such that the recessed part faces the preliminary resin layer;
forming the resin layer by curing the preliminary resin layer; and
separating the stage from the base substrate on which the resin layer is formed.

2. The method of claim 1, wherein:
a state, in which the first non-folding part, the folding part, and the second non-folding part are flat, is defined as a first state,
a state, in which the folding part is folded such that the base substrate corresponds to a shape of the stage, is defined as a second state, and
in the seating of the base substrate on the stage, the base substrate is changed from the first state to the second state.

3. The method of claim 2, wherein in the separating of the stage from the base substrate, the base substrate is changed from the second state to the first state.

4. The method of claim 2, wherein:
in the second state, an extension plane of the first non-folding part and an extension plane of the second non-folding part define a second angle, and
the second angle is substantially equal to the first angle.

5. The method of claim 1, wherein the base substrate is a glass substrate.

6. The method of claim 1, wherein the first angle ranges from 60 degrees to 179.5 degrees.

7. The method of claim 1, wherein:
in the seating of the base substrate on the stage, a filling space is formed between the recessed part and the first part, and
the preliminary resin layer is disposed in the filling space.

8. The method of claim 1, wherein:
the base substrate comprises:
a first base surface, in which the recessed part is defined, and being adjacent to the stage, and
a second base surface facing the first base surface and spaced apart from the stage, and
in the seating of the base substrate on the stage:
the recessed part contacts the preliminary resin layer,
a first portion of the first base surface corresponding to the first non-folding part contacts the second part, and
a second portion of the first base surface corresponding to the second non-folding part contacts the third part.

9. The method of claim 1, further comprising:
pressing the folding part in a direction facing the stage after the seating of the base substrate on the stage,
wherein, in the pressing of the folding part, the preliminary resin layer entirely fills in the recessed part.

10. The method of claim 1, wherein:
the forming of the resin layer comprises fixing a shape of the preliminary resin layer filled in the recessed part, through the curing of the preliminary resin layer, and
in the separating the stage, the fixed resin layer is separated from the stage together with the base substrate.

11. The method of claim 1, wherein the stage comprises a hydrophobic material.

12. The method of claim 1, further comprising surface treating each of the curved surface, the first flat surface, and the second flat surface with a hydrophobic material.

13. A method for manufacturing a display device, the method comprising:
providing a display module comprising a folding display part, a first non-folding display part, and a second non-folding display part, wherein the folding display part is foldable with respect to a folding axis extending in a first direction, and the first non-folding display part and the second non-folding display part are disposed spaced apart from each other in a second direction perpendicular to the first direction, with the folding display part being interposed between the first non-folding display part and the second non-folding display part; and
providing a window on the display module,
wherein the providing of the window comprises:
providing a base substrate comprising a folding part corresponding to the folding display part, a first non-folding part corresponding to the first non-folding display part, and a second non-folding part corresponding to the second non-folding display part, wherein a recessed part is defined in the base substrate in correspondence to the folding part; and
forming a resin layer disposed in at least the recessed part, and
wherein the forming of the resin layer comprises:
providing a stage comprising a first part comprising a curved surface, a second part extending from a side of the first part and comprising a first flat surface, and a third part extending from an opposite side of the first part and comprising a second flat surface defining a first angle with the first flat surface;
forming a preliminary resin layer by applying a resin on the stage such that the resin overlaps at least the first part;
seating the base substrate on the stage such that the recessed part faces the preliminary resin layer;
forming the resin layer by curing the preliminary resin layer; and
separating the stage from the base substrate on which the resin layer is formed.

14. The method of claim 13, wherein:
the base substrate comprises:
a first base surface in which the recessed part is defined, and
a second base surface facing the first base surface, and
the first base surface is disposed adjacent to the display module.

15. The method of claim 13, wherein:
the base substrate comprises:
a first base surface in which the recessed part is defined, and
a second base surface facing the first base surface, and
the second base surface is disposed adjacent to the display module.

16. A window manufacturing apparatus comprising:
a stage comprising:
a first part comprising a curved surface;
a second part extending from a side of the first part and comprising a first flat surface; and
a third part extending from an opposite side of the first part and comprising a second flat surface defining a first angle with the first flat surface, wherein:
a seating surface on which a target substrate is seated is defined by the curved surface, the first flat surface, and the second flat surface, and
a space in which a resin is filled is formed between the target substrate and the first part in a state in which the target substrate is seated on the stage.

17. The window manufacturing apparatus of claim 16, wherein with respect to a reference line being parallel to a normal line at a central point of the first part:
the first flat surface is inclined at a first sub-angle with respect to the reference line, and
the second flat surface is inclined at a second sub-angle with respect to the reference line,
wherein the first angle is defined as a sum of the first sub-angle and the second sub-angle, and
wherein the first angle ranges from 60 degrees to 179.5 degrees.

18. The window manufacturing apparatus of claim 17, wherein the first sub-angle and the second sub-angle are equal to each other.

19. The window manufacturing apparatus of claim 16, wherein the first part, the second part, and the third part have an integral shape.

20. The window manufacturing apparatus of claim 16, wherein on a cross-section, the curved surface has a concave shape having a first radius of curvature.
